(19) United States
(12) Patent Application Publication
(10) Pub. No.: US 2022/0341999 A1
(43) Pub. Date: Oct. 27, 2022

(54) SYSTEMS AND METHODS FOR IMPEDANCE MEASUREMENT OF A BATTERY CELL

(71) Applicant: Iontra LLC, Denver, CO (US)

(72) Inventors: Daniel A. Konopka, Denver, CO (US); John Richard Howlett, III, Centennial, CO (US)

(21) Appl. No.: 17/856,675

(22) Filed: Jul. 1, 2022

Related U.S. Application Data
(63) Continuation-in-part of application No. 17/327,416, filed on May 21, 2021.
(60) Provisional application No. 63/217,660, filed on Jul. 1, 2021.
(60) Provisional application No. 63/028,426, filed on May 21, 2020.

(51) Int. Cl. G01R 31/389; G01R 31/3842

(52) U.S. Cl. CPC G01R 31/389; G01R 31/3842

(57) ABSTRACT

Aspects of the present disclosure involves a system for charging (or discharging) an electrochemical device, where the system may include a processing unit, such as a controller, operably coupled with a first memory and a second memory. The first memory includes a first measurement of an electrochemical device and the second memory includes a second measurement of the electrochemical device. Measurements of the electrochemical device, e.g., voltage and current measurements of a battery, may be interleavingly sampled and alternatingly stored in the respective memories. The processing unit computes impedance to the charge signal from the first measurement and the second measurement.

### CROSS-REFERENCE TO RELATED APPLICATION

This application is related to and claims priority under 35 U.S.C. §119 from U.S. Provisional Application No. 63/217,660 filed Jul. 1, 2021 entitled “System and Methods for Impedance Measurement of a Battery Cell,” the entire contents of which is fully incorporated by reference herein for all purposes. The present application is also a continuation-in-part application of and claims priority to co-pending application Ser. No. 17/327,416 titled “Systems and Methods for Impedance Measurement of a Battery Cell,” which is hereby incorporated by reference herein.

### TECHNICAL FIELD

Embodiments of the present invention generally relate to systems and methods for charging of one or more battery cells, and more specifically to methods for determining impedance of a battery cell, the impedance determination for use in optimizing a charging signal to charge one or more battery cells.

### BACKGROUND AND INTRODUCTION

Many electrically-powered devices, such as power tools, vacuums, any number of different portable electronic devices, and electric vehicles, use rechargeable batteries as a source of operating power. Rechargeable batteries are limited by finite battery capacity and must be recharged upon depletion. Recharging a battery may be inconvenient as the powered device must often be stationary during the time required for recharging the battery. In the case of vehicle battery systems and similarly larger capacity systems, recharging can take hours. As such, significant effort has been put into developing charging technology that reduces the time needed to recharge the battery. However, rapid recharging systems typically require costly high-power electronics for the delivery of high levels of charging current, along with current limit and overvoltage circuitry for preventing over-charging and resulting damage to the working battery. Slower recharging systems are less costly, but prolong the recharging operation, undermining the basic objective of a quick return to service.

Battery systems also tend to degrade over time based on the charge and discharge cycling of the battery system, the depth of discharge and overcharging, among other possible factors. Thus, like the speed of charging, efforts are made to optimize charging to maximize battery life, not over discharge the battery or overcharge the battery while using as much of the battery capacity as possible. Often these objectives are at odds, and charging systems are designed to optimize some attributes at the expense of others.

It is with these observations in mind, among others, that aspects of the present disclosure were conceived and developed.

### SUMMARY

One aspect of the present disclosure related to a method for monitoring an electrochemical device. The method may include the operations of obtaining, via a processing device, a measurement of a first characteristic of an electrochemical device during a first period of a charge waveform applied to the electrochemical device, obtaining, via the processing device, a measurement of a second characteristic of the electrochemical device during a second period of a charge waveform applied to the electrochemical device, the second period occurring after the first period, and calculating an impedance parameter for the electrochemical device based on the measurement of the first characteristic and the measurement of the second characteristic.

Another aspect of the present disclosure involves a system for charging an electrochemical device, where the system may include a processing unit, such as a controller, operably coupled with a first memory and a second memory. The memories may be relatively small dedicated circular buffers of some form of RAM, such as DRAM, SRAM, and the like although other memory types are possible as well as partitioning a memory into distinct blocks of memory. The first memory includes a first measurement of an electrochemical device and the second memory includes a second measurement of the electrochemical device. Measurements of the electrochemical device, e.g., voltage and current measurements of a battery, may be interleaved and alternatingly stored in the respective memories. The processing unit is configured to compute an operational characteristic, such as some representation of impedance to the charge signal, of the electrochemical device from the first measurement and the second measurement.

The system may further include a first multiplexor operably coupled with the first memory and the second memory, where the multiplexor is controlled to sequence storage of the first measurement in the first memory and the second measurement in the second memory. So, for example, the interleaved measurements may similarly be interleaved into the respective memories. In one arrangement, the first measurement is stored in a first memory location of the first memory and the second measurement is stored in a second memory location of the second memory, wherein the first memory location is aligned with the second memory location. Thus, for example with a circular buffer or otherwise various forms of RAM, the system may access the first out memory location of each memory, and the interleaved measurements will be each available. In another example, the system may further include a second multiplexor operably coupled with an analog to digital converter, where the analog to digital converter is operably coupled with the first multiplexor. In this example, the second multiplexor is controlled to alternately access a first measurement circuit to obtain the first measurement and a second measurement circuit to obtain the second measurement, and the analog to digital converter alternatively digitizes the first measurement and the second measurement and provides the digitized measurements to the first multiplexor to sequence storage of the first measurement in the first memory and the second measurement in the second memory.

In yet another example, aspects of the present disclosure involve a system for an electrochemical device involving a processing arrangement to obtain a first measurement of a first current from a first memory, the first measurement of an electrochemical device (e.g., a battery) during a first period of a charge or discharge waveform at the electrochemical device and obtain a second measurement of a second voltage from a second memory, the second measurement of the electrochemical device during a second period of a charge or discharge waveform at the electrochemical device where the second period occurs after the first period. The processing arrangement calculates an impedance characteristic for the electrochemical device based on the first measurement of the first current and the second measurement of the second voltage. The first measurement may be a current amplitude responsive to a charge or discharge signal applied to the electrochemical device and the second measurement may be a voltage amplitude responsive to a charge or discharge signal applied to the electrochemical device, with the controller calculating an impedance ratio from the current amplitude measurement and the corresponding voltage amplitude measurement and obtaining based on the impedance ratio, the impedance characteristic of the electrochemical device.

These and other aspects of the present disclosure are described in additional detail below with reference to the following drawings.

### BRIEF DESCRIPTION OF THE DRAWINCIS

The foregoing and other objects, features, and advantages of the present disclosure set forth herein should be apparent from the following description of particular embodiments of those inventive concepts, as illustrated in the accompanying drawings. The drawings depict only typical embodiments of the present disclosure and, therefore, are not to be considered limiting in scope.

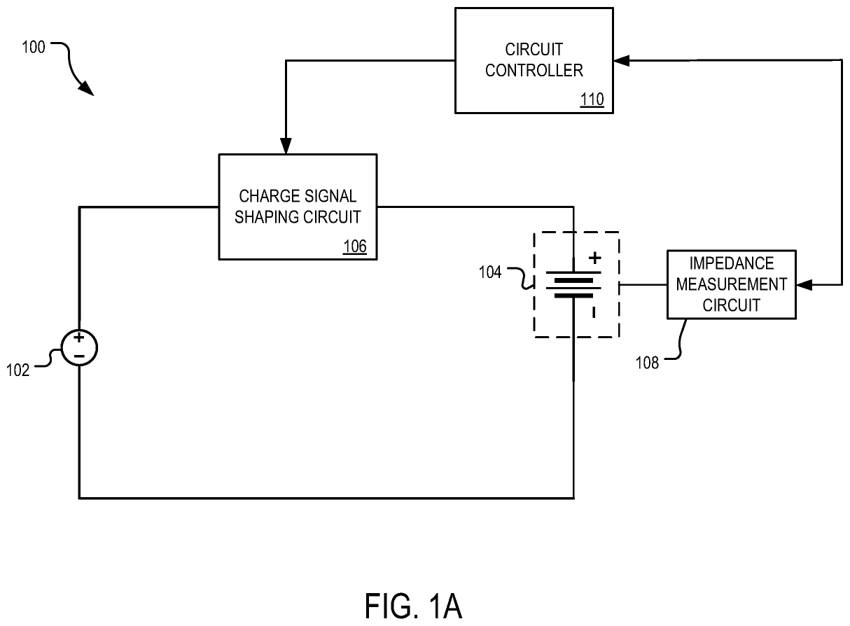

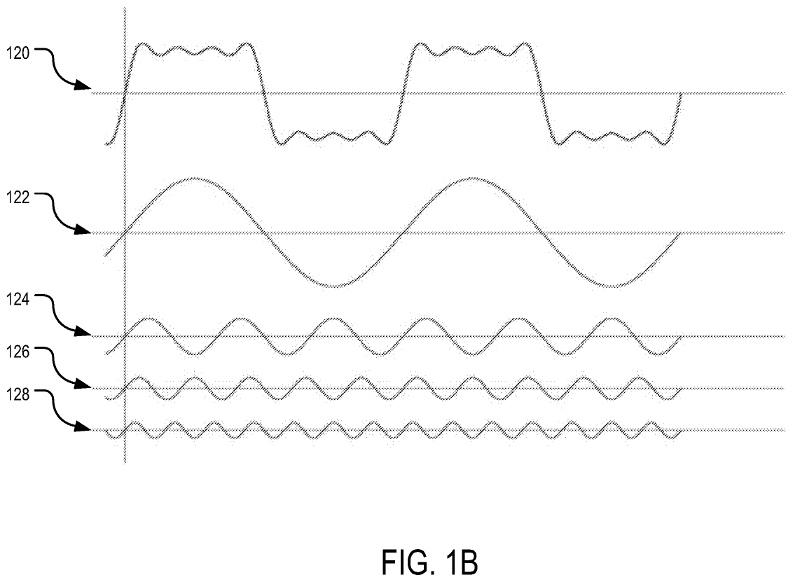

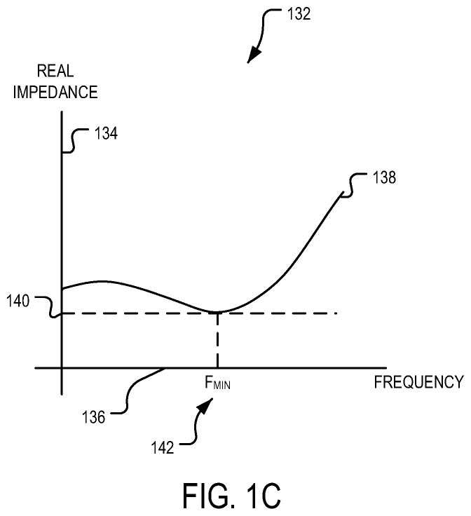

FIG. 1A is a schematic diagram illustrating a first circuit for charging a battery cell utilizing a charge signal shaping circuit in accordance with one embodiment.

FIG. 1B is a signal diagram of a charge signal for a battery cell and the component harmonics of the charge signal in accordance with one embodiment.

FIG. 1C is a graph of measured real impedance values of a battery cell to corresponding frequencies of a charge signal applied to the battery cell in accordance with one embodiment.

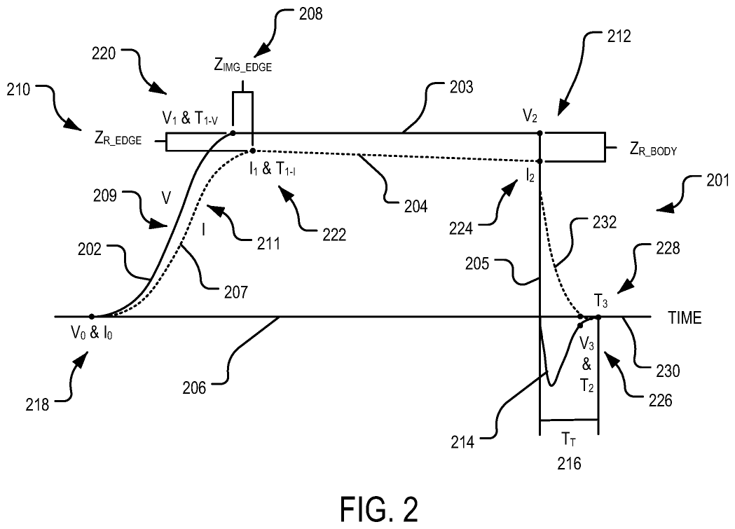

FIG. 2 is a signal diagram of a measured variation in current across a battery cell in response to a voltage-controlled discrete charge period in accordance with one embodiment.

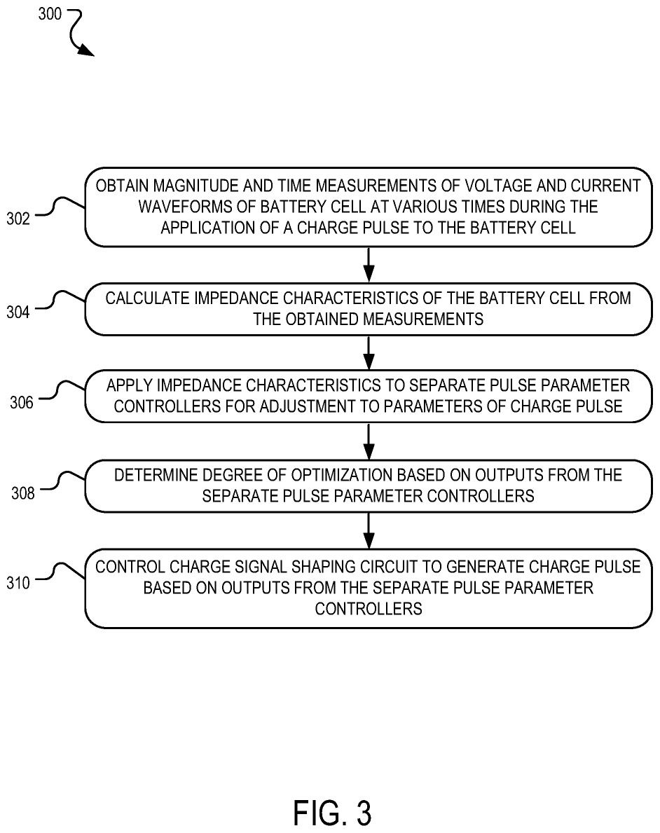

FIG. 3 is a flowchart illustrating a method for determining an impedance of a battery cell at various times based on measured characteristics of waveforms at the battery cell in accordance with one embodiment.

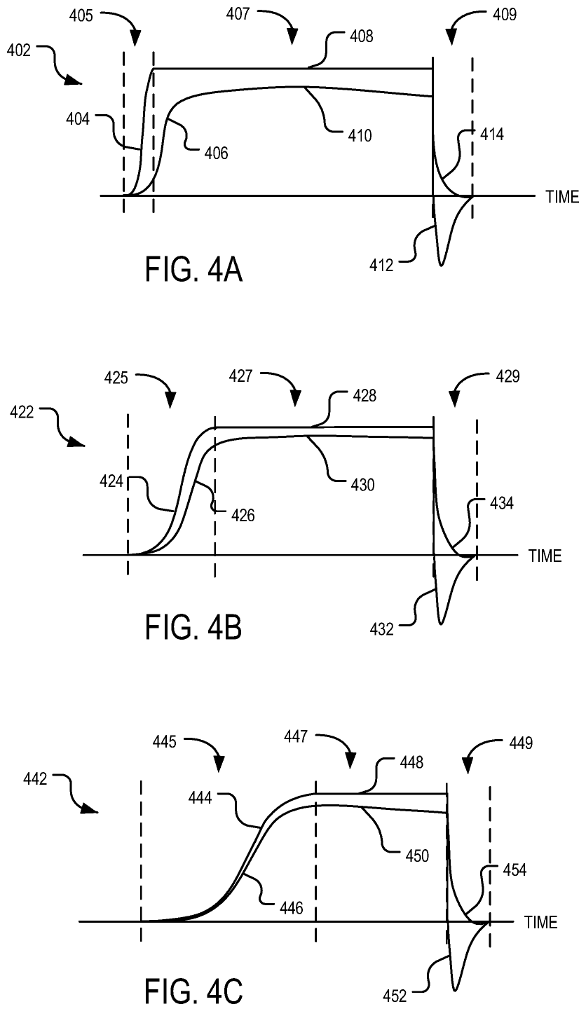

FIG. 4A is a signal diagram of a measured variation in current across a battery cell in response to a first applied voltage discrete charge period in accordance with one embodiment.

FIG. 4B is a signal diagram of a measured variation in current across a battery cell in response to a second applied voltage discrete charge period in accordance with one embodiment.

FIG. 4C is a signal diagram of a measured variation in current across a battery cell in response to a third applied voltage discrete charge period in accordance with one embodiment.

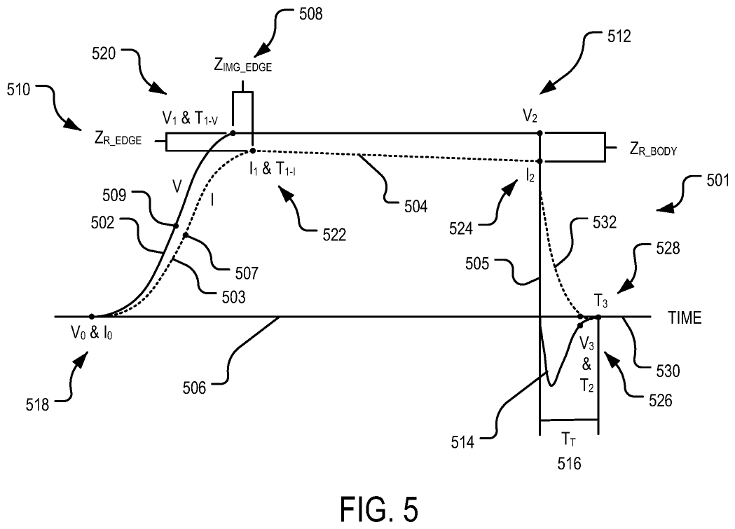

FIG. 5 is a signal diagram of a measured variation in current across a battery cell in response to a voltage-controlled discrete charge period in accordance with one embodiment.

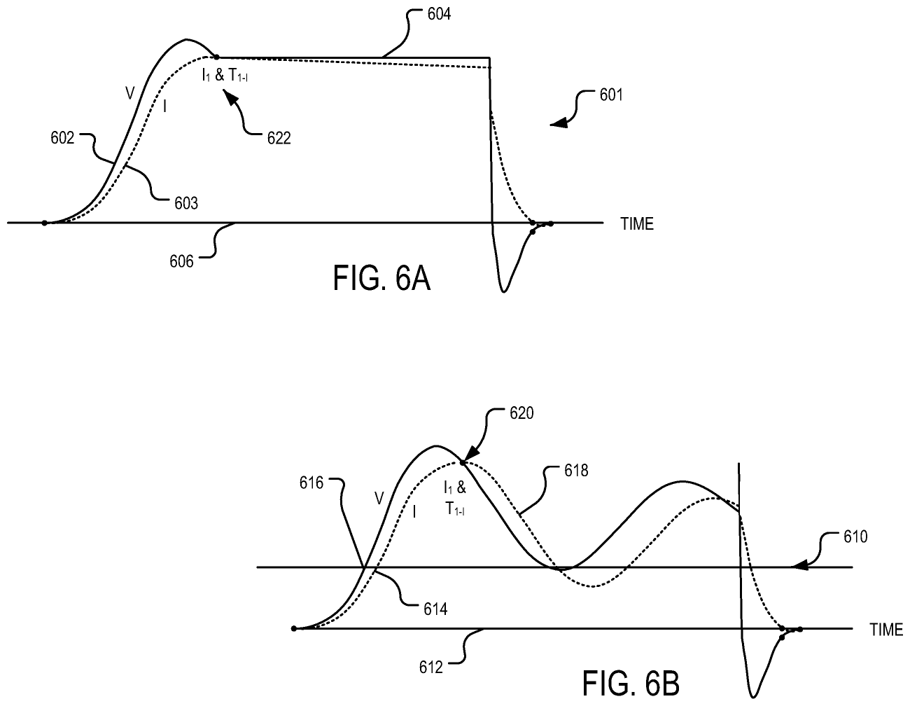

FIG. 6A is a second signal diagram of a measured variation in current across a battery cell in response to a voltage-controlled discrete charge period in accordance with one embodiment.

FIG. 6B is a third signal diagram of a measured variation in current across a battery cell in response to a voltage-controlled discrete charge period in accordance with one embodiment.

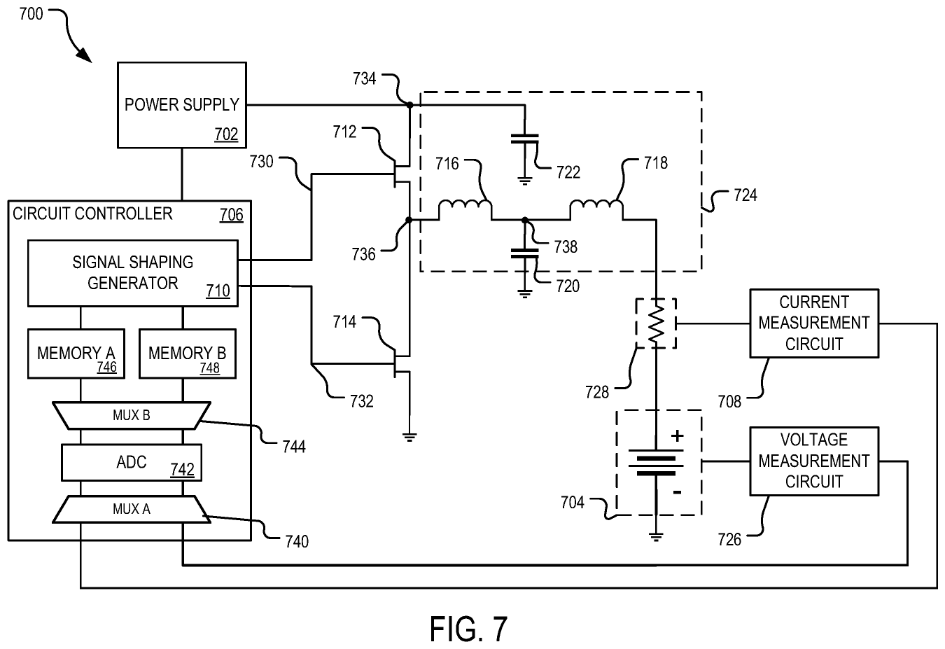

FIG. 7 is a schematic diagram illustrating a second circuit for charging a battery cell based on a measured impedance value in accordance with one embodiment.

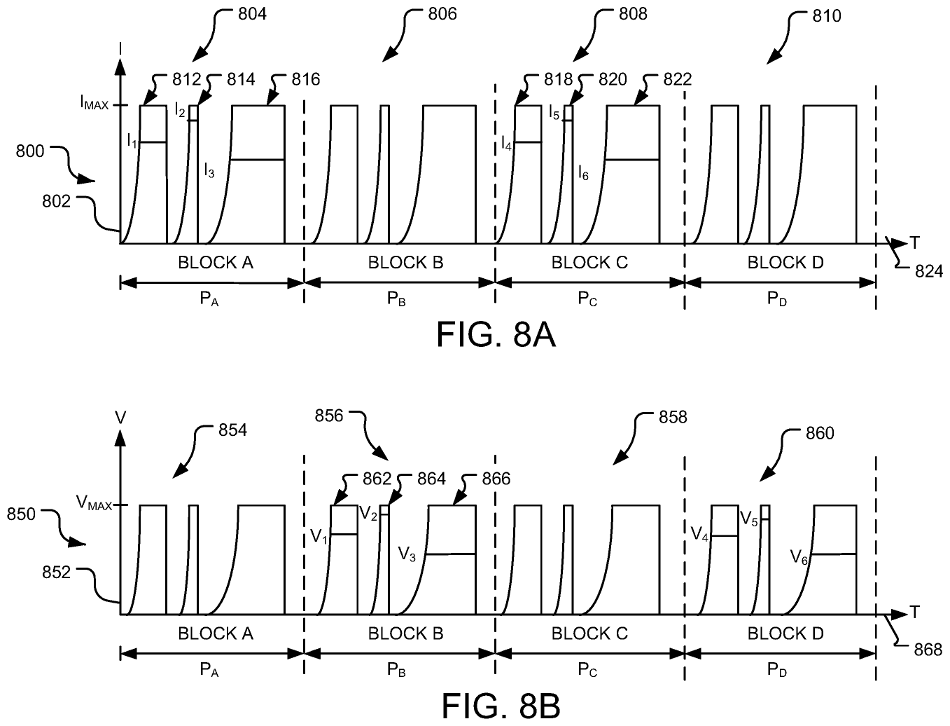

FIG. 8A is a signal diagram of measured currents into a battery cell in blocks of time for determining impedance values at the battery cell in accordance with one embodiment.

FIG. 8B is a signal diagram of measured voltages across a battery cell in blocks of time for determining impedance values at the battery cell in accordance with one embodiment.

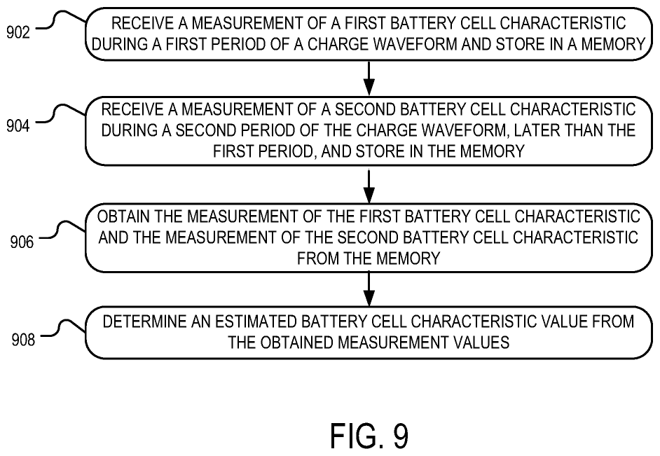

FIG. 9 is a flowchart illustrating a method for determining an impedance parameter of a battery cell based on measurements of the battery cell taken at different time periods in accordance with one embodiment.

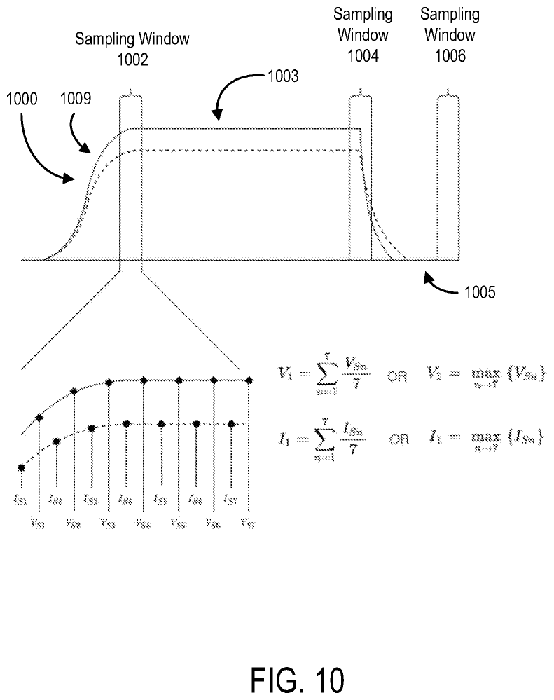

FIG. 10 is a signal diagram illustrating time windows where voltage and current measurements of a charge signal are interleaved for multiplexed storage into respective memory banks.

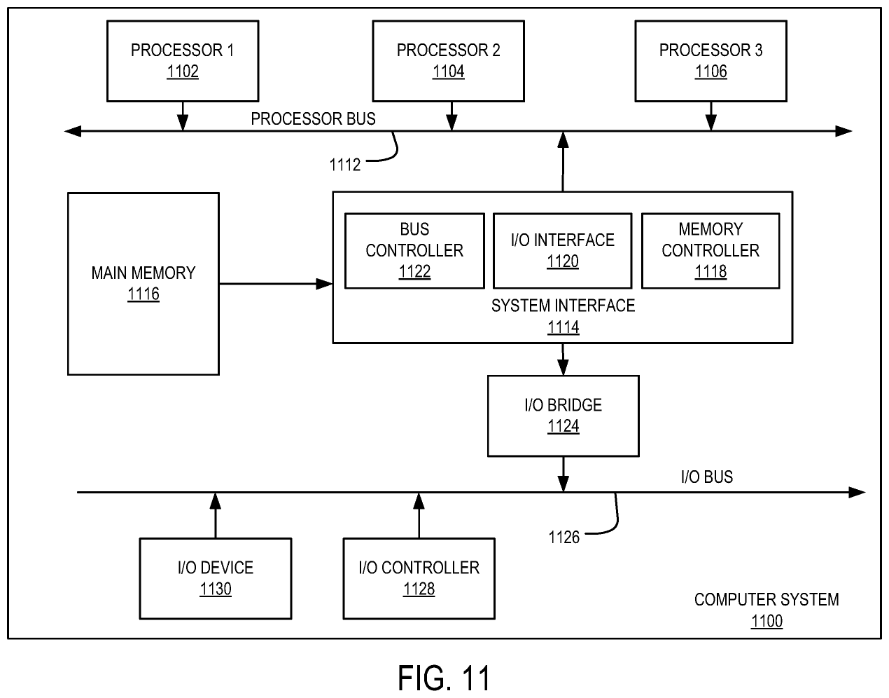

FIG. 11 is a diagram illustrating an example of a computing system which may be used in implementing embodiments of the present disclosure.

### DETAILED DESCRIPTION

In accordance with aspects of the present disclosure, it is beneficial to obtain information indicative of complex impedance to a charging signal being applied to a battery, and use such impedance to optimize the charge signal applied to the battery. Aspects of the disclosure take advantage of the notion that conventional charging techniques are often accompanied by uncontrolled harmonics and such harmonics alter the impedance to the charge signal being applied to the battery. Moreover, various harmonics often increase the impedance to the signal being applied to the battery having a deleterious effect on charging efficiency, capacity retention and cycle life. Similarly, harmonics may decrease the amount of chemical energy stored in the battery relative to the applied charging power, and the overall admittance in the case of discrete charge period methods. Aspects of the present disclosure involve optimizing a charge signal corresponding to a harmonic, or harmonics, associated with minimum real or resistance and/or minimum imaginary or reactance impedance values of a battery cell. Such a charge signal may improve the efficiency when charging the battery cell by reducing lost energy due to high impedance at the electrodes of the battery cell. A charge signal associated with a high impedance at the electrodes of the battery cell may result in many inefficiencies, including capacity losses, heat generation, imbalance in electro-kinetic activity throughout the battery cell, undesirable electro-chemical response at the charge boundary, and damage to the materials within the battery cell that may damage the battery and degrade the life of the battery cell. Further, cold starting a battery with a fast-rising leading edge of a discrete charge period introduces limited faradaic activity as capacitive charging and diffusive processes set in. During this time, proximal lithium will react and be quickly consumed, leaving a period of unwanted side reactions and diffusion-limited conditions, which negatively impact the health of the cell and its components.

Further, changes in the state of charge, temperature, and other factors of a battery cell may alter the impedance at the electrodes of the battery cell. Thus, during charging, the impedance at the battery cell may vary over time as the battery cell heats and/or the state of charge of the battery cell increases. Thus, in addition to understanding the impedance characteristics of a battery cell being charged, measurement of the impedance at the battery cell at different times or stages of a charging sequence as the impedance profile of the battery cell changes may further improve the charging of the battery cell. Moreover, altering charging characteristics based on such impedance changes may further benefit the battery system in various ways.

As such, systems and methods are disclosed herein for determining complex impedance characteristics of one or more battery cells based on the charge signal applied, or to be applied, to the battery cell. Implementations may include measuring the impedance of a battery to, in some instances, determine a frequency component or harmonic that defines, at least a portion, of a waveform shape for charging the battery. Although discussed generally herein as a discrete charge period or charge package, the charge waveform may be of any form or shape and may include both periodic and aperiodic portions. As such, the systems and methods described herein may apply to any type of charge signal that includes at least one harmonic. The impedance values, including both a real component value and/or an imaginary component value, of the battery may be obtained in a variety of ways or methods.

It should be appreciated that references to impedance herein may refer to complex impedance expressed in a polar form in which a magnitude value represents a ratio of a voltage amplitude across the battery cell to a current amplitude through the battery cell and a phase value representing a phase shift by which the current leads, lags, or is in phase with the voltage at the battery cell. The references to impedance herein may also refer to complex impedance expressed in a Cartesian form, derived from the polar form, in which a real component or value represents the resistance at the battery cell and an imaginary component represents the reactance at the battery cell. Although the use of the Cartesian form of impedance with the real component and the imaginary component may be used herein to provide for an easier understanding, the systems and methods described may determine such values from a ratio of a voltage amplitude across the battery cell to a current amplitude through the battery cell (or magnitude of the impedance) and a phase difference of the current signal in relationship to the voltage signal (or phase shift of the impedance). In other instances, different characteristics of the battery cell may be measured, determined, or estimated. For example, a conductance and/or susceptance, or any other admittance aspect, either alone or in combination, of the battery may be measured or obtained during charging of the battery. Still other characteristics of the battery may be obtained and/or estimated, such as power delivered, voltage measurements, current measurements, and the like. The systems and methods described herein may measure or otherwise obtain such values of admittance, power or other representative values indicative of the flow of current to the electrochemical device (e.g., charge current into the device), responsive to the charge waveform and based on some aspect of a defined harmonic of the charge waveform, and use such values to tailor a charge signal. In one example, the tailoring of the waveform involves optimizing, and defining, a harmonic feature of the waveform based on one or more such representative values.

In one implementation, the impedance at the battery cell may be measured or estimated from a discrete charge period of a charge waveform being applied to the battery or from multiple discrete charge periods applied to the battery. For example, aspects of the amplitude and time components of the voltage and current components of the charge signal at the battery cell may be measured and/or estimated. In another example, aspects of the amplitude and time components of the voltage and current components of the charge signal over multiple discrete charge periods or at various times may be measured and/or estimated. Thus, aspects discussed herein with reference to measurements obtained during one discrete charge period of a charge waveform may similarly apply to measurements obtained over multiple discrete charge periods or at other various times of the charge waveform. The measured differences between the amplitude and time components of the voltage and current waveforms may be used to determine or estimate the magnitude, phase shift, real, and/or imaginary values of the impedance at the battery cell. In one example, real and imaginary impedance values may be determined from differences at a leading edge of a charge discrete charge period that is defined from a known harmonic with the differences in the amplitude of the voltage and current waveforms taken at a known point or points of the harmonic/waveform edge. Similarly, aspects of the impedance may be approximated from amplitude measurements of the voltage and current portions at other points of a charge waveform. In still other implementations, the various measurements of the voltage and current waveforms of the charge signal may be adjusted based on weighted values applied to the measurements. In general, several aspects of the voltage and current waveforms of the charge signal may be determined or measured to determine or estimate the impedance at the battery cell. In another implementation, hundreds or thousands of measurements of the voltage and current portion of the charge signal may be obtained and analyzed via a digital processing system. In general, more measurements of the waveforms may provide a more accurate analysis of the effect of the waveforms on the impedance of the battery cell to better determine the frequency effect of impedance, and design the waveform based on the frequency.

In one particular instance, a charge waveform may be applied to a battery cell and parameters associated with different portions of the waveform may be measured or estimated. One or more key impedance parameters may be calculated from the measured portions of the waveform. In some instances, the key impedance parameters may be determined via a processor configured to calculate or estimate the various key impedance parameters from the measured attributes at the battery cell at various sections of a charge waveform. Separate control processes may adjust and/or optimize the components of the charge waveform based on the key impedance parameters. Each controller may represent a separate process working to optimize different parts of the waveform concurrently or individually in sequence. For example, one or more of the impedance parameters may be weighted and a score, error, probability, or other feedback measurement may be determined from the weighted impedance values. Through adjustment of the waveform features, the feedback measurement may be increased until an optimized or highest score is achieved. When an optimized feedback measurement is achieved, the controllers may control the charge waveform based on the calculated feedback measurements. The controllers of the charge waveform may act concurrently with rules, or in a predefined sequence (which may be overridden in the event of certain triggers defined by programmed rules).

In some instances, calculating or estimating the parameters of a battery cell may include obtaining a measurement of a first characteristic of the battery cell during a first block of time and storing the measurement in a storage or memory device and obtaining a measurement of a second characteristic of the battery cell during second block of time later than the first block. For example, a measurement of a current flowing into the battery cell may be obtained from a current measurement circuit and provided to a circuit controller for storage during a first time block of a charging waveform. The charging waveform may be a repeating signal such that a shape of the charging waveform may be the same or similar for each time block of the waveform. At a second time block later than the first time block, a voltage across the battery cell may be measured by a voltage measurement circuit and provided to the circuit controller for storage. The battery cell may then use the stored measurement values to estimate some characteristic or parameter of the battery cell. In one particular example, the stored measurement values may be used to estimate an impedance parameter of the battery cell, although other characteristics such as an estimated power, an imaginary impedance value, a conductance value, a susceptance value, and others. In the example in which an estimated impedance is determined or calculated, the circuit controller may divide the voltage measurement by the current measurement to estimate the impedance over the multiple time blocks of the charge waveform. Such an approach may be utilized by circuit controllers with limited processing capabilities. Thus, the system may be deployed in an environment where more sophisticated and expensive processors and memory are not necessarily available for commercially practical applications. By storing the measurement values, the circuit controller may process the measurements at a speed that matches the processing capabilities of the circuit controller. The calculated or estimated characteristic of the battery cell may be utilized by the circuit controller to shape or otherwise alter a charge waveform used to charge the battery cell, as explained in more detail herein.

The term “battery” and “battery cell” in the art and herein can be used in various ways and may refer to an individual cell having an anode and cathode separated by an electrolyte as well as a collection of such cells connected in various arrangements. A battery or battery cell is a form of electrochemical device. Batteries generally comprise repeating units of sources of a countercharge and first electrode layers separated by an ionically conductive barrier, often a liquid or polymer membrane saturated with an electrolyte. These layers are made to be thin so multiple units can occupy the volume of a battery, increasing the available power of the battery with each stacked unit. Although many examples are discussed herein as applicable to a battery cell, it should be appreciated that the systems and methods described may apply to many different types of batteries ranging from an individual cell to batteries involving different possible interconnections of cells such as cells coupled in parallel, series, and parallel and series. For example, the systems and methods discussed herein may apply to a battery pack comprising numerous cells arranged to provide a defined pack voltage, output current, and/or capacity. Moreover, the implementations discussed herein may apply to different types of electrochemical devices such as various different types of lithium batteries including but not limited to lithium —metal and lithium-ion batteries, lead acid batteries, various types of nickel batteries, and solid-state batteries, to name a few. The various implementations discussed herein may also apply to different structural battery arrangements such as button or “coin” type batteries, cylindrical cells, pouch cells, and prismatic cells.

FIG. 1A is a schematic diagram illustrating an example charge circuit 100 for recharging a battery 104 in accordance with one embodiment. In general, the circuit 200 may include a power source 102, which may be a voltage source or a current source. In one particular embodiment, the power source 102 is a direct current (DC) voltage source, although alternating current (AC) sources are also contemplated. In general, the power source 102 supplies a charge current for recharging a battery cell 104. In some implementations, the circuit 100 of FIG. 1A may include a charge signal shaping circuit 106 between the power source 102 and the battery cell 104 to shape the charge signal for use in charging the battery 104. A circuit controller 110 may be in communication with the charge signal shaping circuit 106 and provide one or more inputs to the charge signal shaping circuit 106 to control the shaping and/or define harmonic components of the charge signal. One particular implementation of the charge shaping circuit 106 is described in greater detail in co-filed U.S. Non-Provisional application Ser. No. 17/232,975 titled “Systems and Methods for Battery Charging”, the entirety of which is incorporated by reference herein.

In some instances, the circuit controller 110 may control the charge shaping circuit 106 to shape the waveforms of the charge signal based on one or impedance measurements or other characteristics of the battery cell 104. For example, the charge signal shaping circuit 106 may be controlled to alter energy from the power source 102 to generate a charge waveform that at least partially corresponds to a harmonic associated with a minimum real impedance value, a minimum imaginary impedance value, a maximum conductance value, an optimal susceptance value, and the like of the battery cell 104. As such, the circuit controller 110 may communicate with an impedance measurement circuit 108 connected to the battery cell 104 to measure cell voltage and charge current, as well as other cell attributes like temperature and measure or calculate the impedance across the electrodes of the cell 104. In one example, impedance may be measured based on the applied waveforms and may include a real or resistance value and an imaginary or reactance value. In another example, impedance may be measured based on the applied waveforms and may include a magnitude value determined from a ratio of a voltage amplitude and a current amplitude and a phase shift value determined from a lag of a current signal in relation to a voltage signal. In general, the impedance of the battery cell or cells 104 may vary based on many physical of chemical features of the cell, including number and configuration of cells, a state of charge and/or a temperature of the cell(s). As such, the impedance measurement circuit 108 may be controlled by the circuit controller 110 to determine various impedance values of the battery cell 104 during recharging of the cell, among other times, and provide the measured impedance values to the circuit controller 110. In some instances, a real component of the measured impedance of the battery cell 104 may be provided to the charge signal shaping circuit 106 by the circuit controller such that energy from the power source 102 may be sculpted into one or more charge waveforms that correspond to a harmonic associated with a minimum real impedance value of the battery cell 104. In another example, the circuit controller 110 may generate one or more control signals based on the received real impedance value and provide those control signals to the charge signal shaping circuit 106. The control signals may, among other functions, shape the charge waveform to include a harmonic component corresponding to the real impedance value.

Waveforms generated from a conventional power supply may be comprised of multiple harmonic components. For example, FIG. 1B illustrates an example a sequence of waveforms 120, which could be applied to charge a battery cell 104. The waveform signal 120 is comprised of several sinusoidal signals, or harmonics, of different frequencies. In the illustrated example, the waveform signal 120 is a summation of sinusoidal signal 122 of a first frequency, sinusoidal signal 124 of a second frequency, sinusoidal signal 126 of a third frequency, and sinusoidal signal 128 of a fourth frequency. In any given situation, more or fewer frequency components are possible, and the example of four is used merely for purposes of illustration and example. The combination of the sinusoidal harmonics 122-128 comprise the waveform signal 120 of FIG. 1B. Aspects of the present disclosure involve, controlling the shape of the waveforms, including magnitude and timing of harmonics, in such a signal and using that shaped signal to charge a battery cell, where various aspects of the waveforms, e.g., a leading edge, a body, and/or a trailing edge, may be created through a harmonic or combination of harmonic components. As explained in co-filed U.S. Non-Provisional application Ser. No. 17/232,975 titled “Systems and Methods for Battery Charging,” the impedance at the battery cell 104 due to the application of a waveform signal 120 may be dependent upon the harmonics or frequencies contained within the charge signal. For a so-called square wave signal, for example, rather than being a sequence of set DC voltage levels, the signal may include a sequence of pulses that each consist of various frequency harmonics as introduced with regard to FIG. 1B. Moreover, the uncontrolled implicit harmonics of the pulses may be associated with relatively high impedances at the battery cell 104 should such an uncontrolled pulse signal be applied in charging, lowering the efficiency of the square wave to charge the battery cell 104. As such, generating or shaping a charge signal to remove or diminish harmonics at which high impedance is present at the battery cell 104 may improve the efficiency in charging the battery, reduce heat generated during charging, reduce damage to the anode or cathode, reduce charging time, allow for more capacity to be used, and/or increase battery life.

FIG. 1C is a graph 132 illustrating a relationship between a real impedance value (axis 134) of a battery cell 104 to corresponding harmonics (illustrated as logarithmic frequency axis (axis 136)) included in a charge signal applied to the battery cell. The plot 138 illustrates real impedance values across the electrodes of a battery cell 104 at the various frequencies of a sinusoidal component of a charge signal that may applied as a charge signal. As shown, the real impedance values 138 may vary based on the frequency of the charge signal, with relatively lower impedances between initially higher impedances at lower frequencies and then a relatively rapid increase in real impedance values at harmonics higher than the frequency at which the lowest impedance is found. The plot 138 of real impedance values for the battery cell 104 indicates a minimum real impedance value 140 that corresponds to a particular charge signal frequency 142, labeled as f_{Min}. The plot of real impedance values 138 for the battery cell 104 may be dependent on many factors of the cell, such as battery chemistry, state of charge, temperature, composition of charge signal, and the like. Thus, the frequency f_{Min} 142 corresponding to the minimum real impedance value 140 of the battery cell 104 may similarly be dependent upon the characteristics of the particular battery cell 104 under charge. The frequency f_{Min} 142 may correspond to other aspects of the battery cell 104, such as the configuration of the cells in a pack and the connections between the cells in the pack.

In one implementation, the charge signal shaping circuit 106 may provide, in response to one or more control signals from the circuit controller 110, a charge discrete charge period similar to that illustrated in FIG. 2. FIG. 2 is a signal diagram of a measured voltage 202 across a battery cell (illustrated as the solid line 202 labeled “V”) and a measured current 204 at battery cell (illustrated as the dashed line 204 labeled “I”) versus time 206 in response to a charge signal applied to the battery cell in accordance with one embodiment. In general, the charge signal shaping circuit 106 may control the voltage 202 or current 204 across battery cell to include a shaped front edge 209 (sometimes corresponding to a harmonic associated with an impedance measurement at the battery cell), a constant or near constant body portion 203 (which may correspond to an upper voltage limit of the power source 102 or a maximum voltage or current level the system may apply to the battery at the time), and a sharp falling edge 205. However, for a voltage-controlled variant of the circuit 100, the current 204 component of the discrete charge period 201 may lag behind the voltage component 202. More particularly, the current 204 at the battery cell may take some time to return to zero after the voltage 202 to the battery is removed at the falling edge 205 of the discrete charge period 201. As this delay in the current 204 at the battery returning to zero may add additional inefficiencies to the overall discrete charge period particularly if it is intended to a have rest period where there is no applied voltage or charge current to the battery, some implementations of the discrete charge period 201 may include the voltage 202 of the charge signal controlled to drive the voltage below a transition voltage corresponding to a zero current at the battery cell, represented in FIG. 2 as portion 214 of the discrete charge period. In general, the transition voltage is the voltage of a charge signal at which current flow into the battery is reversed and may be similar to the float voltage of the battery cell. In particular, driving the voltage 214 below the transition voltage, which may be zero, for a period of time following the falling edge 205 of the discrete charge period may drive the current 204 to zero amps at a faster rate as compared to a discrete charge period without such a momentary negative voltage portion. The duration T_{T} 216, during which the voltage 214 is controlled below the transition voltage corresponding to a zero current, may be determined or set by the circuit controller 110 to minimize the time for the current 204 at the battery cell 104 to return to zero amps. Once the current 204 has returned to zero amps for a particular rest period, another discrete charge period 201 may be applied to the battery cell 104. In another instance, the resting voltage 230 may be stabilized without external control in addition to the current 204 returning to zero amps prior to the next discrete charge period 201 being applied to the battery cell 104. In either instance, it may be desirable to minimize or control the amount of discharge that occurs at the end of the discrete charge period 201 before the application of another charge discrete charge period.

As mentioned above, the circuit controller 110 may control an impedance measurement circuit 108 to measure the impedance at the battery cell 104 and use such measurements to control the charge signal shaping circuit 106 to generate one or more additional or future charge discrete charge periods based on the measured impedances. In particular, as the impedance at the battery cell 104 may correspond to the harmonics of the charge signal, efficiency of charging the battery cell may be improved by limiting the harmonics in a charge signal to those at or near the frequency f_{Min} 142 and/or shaping the leading edge corresponding to those frequencies. To generate such a charge signal, the circuit of FIG. 1A may be configured or designed to obtain impedance values at the battery cell 104 at various points during a discrete charge period or over multiple discrete charge periods to determine the impedance profile of the battery cell 104 and adjust additional or future charge periods in response. In other examples, the circuit controller 110 may control the impedance measurement circuit 108 to obtain other characteristics of the battery cell 104 and/or charge signal applied to the battery cell and use the obtained characteristics to estimate an impedance at the battery cell. For example, impedance values of the battery cell 104 may be measured or estimated based on amplitude and time features of the voltage waveform 202 and/or the current waveform 204 measured at the battery cell by the impedance measurement circuit 108. Further, the amplitude and time features of the waveforms 202, 204 may be measured at different sections of an applied discrete charge period or multiple applied discrete charge periods to determine or estimate the impedance at the battery cell 104. The determined or estimated impedance values of the battery cell 104 may then be used by the circuit controller 110 to adjust future discrete charge periods 201 of the charge signal to improve the efficiency of the charge signal in recharging the battery cell 104.

FIG. 3 is a flowchart illustrating one method for determining impedance values of a battery cell at various times based on measured characteristics of waveforms at the battery cell in accordance with one embodiment. The operations of the method may be performed by components of the impedance measuring circuit 108, perhaps in response to one or more control signals provided by the circuit controller 110. Other components of the circuit 100, however, may perform one or more of the operations of the method 300. Further, the measurements of the waveforms may be obtained through one or more hardware components, one or more software programs, or a combination of hardware and software components. Also, one or more of the operations described may not be performed and the operations may be performed in any order.

Beginning in operation 302, the impedance measurement circuit 108 may obtain amplitude and/or time measurements of voltage and current waveforms at the battery cell 104 at various times during the application of the discrete charge period to the battery cell 104. As explained above and using the voltage 202 and current 204 waveforms of FIG. 2 as examples, a voltage waveform (such as waveform 202) or a current waveform (such as waveform 204) may be provided to a battery cell 104 by the charge signal shaping circuit 106. In the particular example shown, the circuit 100 of FIG. 1A may include voltage-controlled components such that the voltage waveform 202 controls the recharge of the battery cell 104. In alternate implementations, the circuit 100 may include current-controlled components such that a current waveform is shaped by the charge signal shaping circuit 106 to recharge the battery cell 104. Regardless of the type of waveform applied, a voltage at the battery 104 and a measured current at the battery at various times and in response to the discrete charge period applied to the battery cell may be determined or measured. In one implementation, the impedance measurement circuit 108 may obtain a first voltage measurement V₀ and a first current measurement I₀ may be obtained at a first time 218. In one implementation, the first time 218 may correlate to a time when the current at the battery cell 104 is zero amps before the application of the discrete charge period 201 to the battery cell 104. Although the current at time 218 may be zero amps, voltage V₀ may be a floating voltage of the battery cell 104. Further, although illustrated in the same, the represented values of the voltage component 202 and the current component 207 may be scaled and overlaid such that the signals may be illustrated in the same plot, despite being measured in different units. For example, x-axis 206 may represent both zero amps for the current plot 207 and a transition voltage value (in some instances more or less than a zero value) for the voltage plot 202.

Additional voltage and current measurements may be taken later corresponding to the waveforms of the discrete charge period 201. In particular, the impedance measurement circuit 108 may measure the voltage V₁ 220 at the peak of the leading edge 209 of the voltage waveform 202. In addition, the impedance measurement circuit 108 may measure a time difference T_{1-V} between the initial voltage measurement V₀ and the time at which voltage V₁ 220 occurs. The time difference T_{1-V} may be used, as explained below, to determine a reactance value or phase shift value of the impedance at the battery cell 104. In a similar manner, the impedance measurement circuit 108 may measure the current I₁ 222 at the peak of the leading edge 211 of the current waveform 207. Also, the impedance measurement circuit 108 may measure a time difference T_{1-I} between the initial current measurement I₀ and the time at which current I₁ 222 occurs. In this illustrated example, the current waveform 204 is delayed in relation to the controlled voltage waveform 202 such that T_{1-I} occurs after T_{1-V}. Additional amplitude values of the voltage waveform 202 and the current waveform 204 may be taken at the falling edge 205 of the discrete charge period 201. In particular, the impedance measurement circuit 108 may measure the voltage V₂ 212 and the current I₂ 224 at the occurrence of the falling edge 205 of the discrete charge period 201. Generally, due to the impedance at the battery cell 104, less than all of the voltage 202 of the discrete charge period 201 is converted to charge current 204 such that there is some difference between the applied voltage and the received current at the battery cell 104.

Still additional time measurements may be taken by the impedance measurement circuit 108. In one instance, a voltage V₃ and time difference T₂ 226 between the initial voltage measurement V₀ and the time at which voltage V₃ occurs may be obtained when the current waveform 204 returns to zero amps. In some instances, time difference T₂ 226 may be referred to as the fade time as a measure of the time to bring the current waveform 204 to zero amps. In some instances, the voltage V₃ may be below the transition voltage for the battery cell 104 to aid in driving the current to zero amps. However, the charge signal for the battery cell 104 may be controlled to wait until the voltage and current at the battery cell 104 returns to a rest state corresponding to zero amps and the voltage at the transition voltage for the battery cell. Thus, the impedance measurement circuit 108 may further measure a time difference T₃ 228 between the initial voltage measurement V₀ and the time at which voltage the voltage waveform 202 returns to the transition voltage and the current waveform 204 returns to zero amps. In some instances, an additional rest period may be added to the charge signal before an additional discrete charge period is generated for the battery cell 104 to prevent inefficiencies in the charge signal.

It should be appreciated that any number and type of characteristics of the voltage and current waveforms 202, 204 may be measured or determined by the impedance measurement circuit 108 or the circuit controller 110. For example, other amplitudes of the voltage waveform 202 and/or amplitudes of the current waveform 204 may be measured and a time difference of the occurrence of such amplitudes may be determined. Further, the points of the discrete charge period 201 at which the measurements are taken may be dependent upon the shaping of the discrete charge period by the circuit 100 as the measurements may be used to determine the characteristics of the shaped charge period, as described in more detail below.

In operation 304, impedance measurement circuit 108 or the circuit controller 110 may calculate or estimate one or more impedance characteristics of the battery cell based on the measured characteristics of the charge waveform 201. Further, the calculated or estimated impedance characteristics or other characteristics of the battery cell response may correspond to difference sections or portions of the discrete charge period 201. For example, the impedance measurement circuit 108 may determine a ratio of the amplitude values measured at V₁ 220 and I₁ 222 to estimate a real impedance value or impedance magnitude at the peak of the leading edge portion 209 of the discrete charge period 201. In one implementation, the real impedance value 210 at the peak may be calculated based on Z_{R_EDGE}=(V₀−V₁)/(I₀−I₁). In a similar manner, the impedance measurement circuit 108 may determine a ratio of the amplitude values of V₂ 212 and I₂ 224 to estimate a real impedance value or impedance magnitude at the end of the body portion of the discrete charge period 201 through the equation Z_{R_BODY}=(V₀−V₂)/(I₀−I₂). However, the estimated real impedance Z_{R_BODY} may be approximated as the portion of the discrete charge period 201 at which the measurements V₂ 212 and I₂ 224 are taken may include many undistinguishable harmonics such that Z_{R_BODY} may include unknown reactance portions. Such difficulties are generally not present in the calculation of Z_{R)EDGE} as the leading edge 209 of the discrete charge period 201 may comprised of a single harmonic.

In a similar manner, the, phase shift, reactance, or imaginary values of the complex impedance of the battery cell 104 may be determined or estimated. For example, the impedance measurement circuit 108 may determine a difference in the time T_{1-V} and T_{1-I} and utilize the measured time difference to estimate an imaginary impedance value 208 at the peak of the leading edge 209 portion of the discrete charge period 201. In some instances, Z_{IMG_BODY} may be roughly approximated by measuring the impedance characteristics during the time of the fade duration T_{T} 216. In particular, the imaginary component of the impedance at the falling edge 205 may relate to the duration T_{T} 216 of the fade portion of the discrete charge period 201 such that the imaginary component may be estimated based on the measured duration T_{T} 216. In general, many aspects of the impedance of the battery cell 104 may be determined or estimated based on any number of measurements of the discrete charge period 201 applied to the battery cell 104.

In operation 306, the circuit controller 110 may apply one or more of the calculated or determined impedance characteristics to one or more discrete charge period parameter controllers to determine adjustments to the shape of the discrete charge periods of the charge signal provided to the battery cell 104. In particular, the controllers may utilize the impedance measurements or estimates as inputs to the controllers. In some instances, the determined impedance values may be weighted to adjust the effect of the measurements against other measurements or estimates. In general, any aspect of the waveforms 202, 204 may be weighted, not necessarily just against the impedance values, but a variety of parameters including peak values, % time utilization (where a square pulse at 50% duty would be 50% utilization, DC would be 100%), and the like.

In operation 308, the discrete charge period parameter controllers may adjust aspects of the charge waveform 201 to achieve an optimized charge waveform shape. For example, separate waveform parameter controllers may be configured to adjust or optimize a corresponding portion of the charge waveform 201. In one particular implementation, the waveform parameter controllers may include a controller to optimize a harmonic of the leading edge portion 209 of the discrete charge period 201, a controller to optimize the duration of the body portion 203 of the discrete charge period, a controller to optimize the lowest voltage magnitude at the bottom of the fade portion 214 of the discrete charge period, and/or a controller to optimize the rest period of the discrete charge period before a new discrete charge period is generated. For example, the Z_{R_BODY} and/or Z_{R_EDGE} determined above may be utilized to determine the harmonic of the leading edge portion 209 of the discrete charge period 201. Other aspects or characteristics of the discrete charge period may also be optimized by one or more controllers. Each discrete charge period parameter controller may receive an aspect of the impedance measurements or estimations, voltage measurements, current measurements, and the like of the charge waveform 201. Further, each controller may adjust weighting applied to the inputs to generate a highest optimization value for the corresponding portion of the discrete charge period 201 or to minimize damage to the battery cell 104, as explained in more detail below. Such optimization may occur separately or concurrently by the discrete charge period parameter controllers. In one implementation, the controllers may execute sequentially based on one or more rules to determine the sequence of the execution. Further, the sequence of controller execution may be adjusted based on one or more event triggers obtained from the measurements of the charge waveform 201.

In operation 310, the circuit controller 110 may control the charge signal shaping circuit 106 to generate a discrete charge period based on the outputs from the discrete charge period parameters controllers. In general, the outputs from the discrete charge period parameter controllers provide an optimized discrete charge period 201 for applying charge to the battery cell while minimizing or reducing the impedance at the battery cell electrodes. The translation of the controller outputs may generate the control signals for the shaping circuit 106 to adjust the shape of the discrete charge period to optimize the charge signal. For example, the discrete charge period parameter controller corresponding to the harmonic of the leading edge 209 of the discrete charge period 201 may output a frequency for the leading edge to optimize or reduce high frequency harmonics from the leading edge. The circuit controller 110 may then generate one or more control signals for the shaping circuit 106 to adjust the harmonic of the leading edge of the discrete charge period to correspond to the output of the controller. Other aspects of the discrete charge period may be similarly controlled based on the output of the discrete charge period parameter controllers, such as the duration of the discrete charge period and the voltage below the transition voltage for the fade portion of the discrete charge period. In this manner, the calculated or estimated impedance of the battery cell 104 may be used to adjust or control the shape of charge waveforms provided to the battery cell.

In some instances, the circuit controller 110 may consider a state of charge or other characteristic in addition to the measured or estimated impedance values to control the charge signal shaping circuit 106 to generate a discrete charge period based on the obtained impedance measurements above. For example, the battery cell 104 may be determined, by the circuit controller 110, to have a state of charge below 10% with a float voltage below a nominal voltage at the start of a charging session. After obtaining the impedance measurements or determinations during a discrete charge period as explained above, the circuit controller 110 may control a discrete charge period generating circuit to adjust the discrete charge period in response to the determined impedances. For example, a subsequent discrete charge period may be controlled to have a similar shape as that illustrated in FIG. 2. More particularly, based on the impedance measurements or estimations discussed above and a determination of a start of charge of the battery cell 104, the sinusoidal leading edge 209 of the subsequent discrete charge period 201 may be controlled to match a frequency that is above a frequency associated with a minimum impedance of the battery cell. The frequency of the leading edge 209 may be selected by the circuit controller 110 such that the impedance at the battery cell 104 during the leading edge 209 is within a particular tolerance of the measured or calculated impedance values, such as within 12% of a measured minimum impedance (Zₘᵢₙ), a measured real impedance (Zᵣ), a calculated modulus impedance (Z_{mod}), or any other impedance-based measurement or calculation.

The circuit controller 110 may then apply a constant voltage, sloped, or shaped for the body portion 203 of the discrete charge period 201. During the body portion, the current may, in some instances, continue to rise as diffusive processes within the battery cell 104 may still be transient. In such instances, the duration of the body 203 may be adjusted by the circuit controller 110 such that the current peaks at the midpoint of the body 203. This may provide for the current to return, at the end of the body 203, to the same or similar value at the beginning of the body 203 portion, due to the onset of mass transport limitations and increasing voltage gradients between components within the cell. At the trailing edge 205 of the discrete charge period 201, the current may lag the voltage signal but may ultimately fall to zero magnitude. In some instances, the period 216 for the current to fall to zero magnitude may be controlled to be within an acceptable period (such as 15% of the leading edge period). In other instances, the current may be uncontrolled when returning to zero amps after the trailing edge 232 of the discrete charge period 201. This may provide for a lower peak voltage and peak current for a given target charge rate of the battery cell 104, which may minimize polarization, gas evolution, and temperature increase in the battery cell 104. A suitable rest period between discrete charge periods may be based on the duration of the leading edge 209 and body 203 of the charge signal and may be applied to allow the battery cell 104 to dissipate additional heat while maintaining the target charge rate.

At a state of charge from 35% to 65%, the impedance of the battery cell 104 may become increasingly sensitive to peak voltage and peak current of the discrete charge period. In response, the circuit controller 110 may adjust the harmonic of the body portion 203 of the discrete charge period 201 to center around the minimum impedance frequency, while the harmonic associated with the leading edge 202 may be selected to yield a narrower sinusoidal signal (a leading edge 209 with a shorter period). These alterations to the discrete charge period may result in a higher average impedance at the battery cell 104 due to the faster leading edge, such as up to 25% of the minimum impedance. As such, the current may require additional time to approach zero at the trailing edge 205 of the discrete charge period 201. To decrease the time necessary for the current to stabilize to zero amps indicating depolarization of the cell, the voltage dip 214 at the end of the discrete charge period 201 may be decreased to as much as 2.6V instead of returning to the cell's float voltage as above. This voltage dip 214 may be held for a period that allows the current 232 to approach zero within 15% of the leading edge period, and is then gradually raised to the float voltage at a gradient to minimize partial discharge due to current overshoot below zero as well as current oscillation around zero.

Near the maximum allowable average voltage (˜80% SOC) of the battery cell 104, the impedance of the battery cell may necessitate less variation between the frequency of the leading edge 209 and the frequency of the body 203 of the discrete charge period 201. In such circumstance, the discrete charge period 201 may be controlled to within a 22% deviation from the minimum impedance. As the anode and cathode of the battery cell 104 are near upper and lower bounds of lithium concentration, respectively, the impedance of the battery cell 104 may provide for a longer rest period between charge periods while becoming less sensitive to peak voltage and current values for a given charge rate. Adjustment to the discrete charge period 201 allows the charge system to maintain efficient charging with lower polarization and without excessive heat, electrochemical side reactions, or capacity loss.

In other instances, a microcontroller or other digital-based measuring system may be utilized to calculate impedance of the battery cell 104 and control the charge waveform 201 in response. In particular, three voltage measurements of a voltage signal, such as voltage signal 202, may be obtained by a microcontroller and three current measurements of a current signal 204 may be obtained. The measurements may be obtained at the same time in the time domain in the time domain and may therefore be used to calculate two impedance values, Z₁ and Z₂. For example, measurements V₁ and I₁ may be obtained at the same time within the time domain of the discrete charge period. Additional measurements of the waveforms 202, 204 may also be obtained, as described above. The impedance values Z₁ and Z₂ may be used in a similar manner as described above to determine one or more features or aspects of a charge signal and may be utilized by the control circuit 110 to control aspects of the circuit 100 to shape the charge signal accordingly to generate the optimized charge signal from the combination of the controlled waveform.

In many instances, the current through the battery cell 104 corresponds to the shape and characteristics of the voltage of the discrete charge period (for a voltage-controlled discrete charge period). FIG. 4A is a diagram of a voltage component 404 and a current component 406 of a discrete charge period 402 applied to a battery, with the voltage and current both measured. Similar to FIG. 2, the discrete charge period 402 is generated through control of the voltage 404 of the signal 402 and may include a leading edge section 405, a body section 407, and a trailing section 409. In the example illustrated in FIG. 4A, the voltage component 404 of the leading edge 405 may include a sharp edge reflective of a relatively high frequency harmonic. However, due to the impedance at the battery cell 104 associated with the leading edge harmonic, the current at the battery cell (illustrated at curve 406) may rise slower than the voltage and be delayed relative to the voltage. As the impedance at the battery cell 104 corresponds to a ratio of the voltage 404 and the current 406 components, it can be seen that a relatively high frequency leading edge harmonic of the discrete charge period 402 is associated with some impedance that effects the current component of the signal. Further, as shown in FIG. 4A, the voltage 408 may be controlled, in a body portion 407 of the discrete charge period 402, to be at a constant value. However, the response in the current component 410 of the discrete charge period 402 may continue to rise through a portion of the body section 407 due to the impedance of the battery cell 104, which is illustrated in FIG. 4A by the separation of the voltage signal 408 and the current signal 410 in the body portion. The deviation between the voltage signal 408 and the current signal 410 in FIG. 4A illustrates an approximation of the real component or magnitude of the impedance at the battery cell 104 and the delay in the current signal responding to the leading edge of the applied voltage 408 represents an imaginary component or phase shift of the impedance. Plots of the voltage component 408 and the current component 410 may be scaled and overlaid to generate the signal diagrams of FIGS. 4A-4C. The rate at which the current rises in the body section 407 may relate to the transition of the voltage signal 404 from the leading edge to the body section 407. Further, as mentioned above, the duration of the body portion 407 of additional or future discrete charge periods may be controlled such that the peak of the current 410 in the body section 407 occurs at the midpoint of the body section. Therefore, in some instances, a downward slope of the current component 410 of discrete charge period 402 during the body portion 407 may be monitored and/or measured and a trailing edge portion 409 of the discrete charge period may begin at a point when the current is projected to return to a similar current as at the beginning of the body portion. At the trailing edge of the discrete charge period 402 and as described above, the voltage 412 may be driven below the transition voltage for a period of time to drive the current 414 to zero amps at a faster rate as compared to a discrete charge period without such a shape.

In another instance of a discrete charge period 422 illustrated FIG. 4B, the leading edge 425 of the discrete charge period 422 may be defined by a relatively lower frequency harmonic (a less sharp rate relative to the discrete charge period of FIG. 4A)) during the leading edge section 425. The lower frequency harmonic leading voltage edge is associated with a lower impedance that is reflected by the current 426 portion of the discrete charge period 422 more closely following the curve of the voltage-controlled portion 424, both in amplitude and in time. Further, as the transition from the leading portion 425 to the body portion 427 is less severe, again relative to the discrete charge period of FIG. 4A, the apex in the current portion 430 may be similarly less pronounced such that the current amplitude and/or shape more closely mirrors the voltage shape during the body portion. A similar voltage dip 432 in the trailing portion 429 of the discrete charge period 422 as illustrated in the discrete charge period of FIG. 4A may be present in the discrete charge period 422 of FIG. 4B to drive the current 434 to zero amps in preparation for the transmission of another charging waveform.

In yet another example of a discrete charge period 442 as illustrated in FIG. 4C, the leading edge 445 of the voltage signal 444 may be defined by an even lower frequency harmonic as compared to those of FIGS. 4A and 4B defining an even flatter rise. In this instance, the current 446 portion of the discrete charge period may even more closely mirror the curve of the voltage-controlled portion 444 in comparison to the discrete charge periods of FIGS. 4A and 4B. However, the current 450 during the body portion 447 may have a small to no apex as previously mentioned, but may instead gradually decrease as the voltage 448 is maintained at a constant due to diffusive processes within the battery cell 104. This discrete charge period 442 example may also include a voltage dip 452 in the trailing portion 449 of the discrete charge period 442 to drive the current 454 to zero amps.

Shaping the discrete charge period to charge a battery cell 104 may include a balancing of efficiency and delivery of maximum power per period. For example, the discrete charge period 402 of FIG. 4A may provide a large amount of charge power as the voltage reaches the peak value rapidly such that the discrete charge period approaches a square-wave shape. However, the sharp rise in the leading section 405 of the discrete charge period 402 followed by the sharp transition to the body portion 407 may introduce high harmonics in the signal. As discussed above with relation to FIG. 10, such high harmonics may cause a large impedance at the battery cell 104, resulting in large inefficiencies in the charging of the battery. Alternatively, although the discrete charge period 442 of FIG. 4C may reduce or minimize the harmonics within the discrete charge period that provide a high impedance at the battery cell 104 due to the slower leading edge 445, the amount of mean power provided to the battery cell 104 (corresponding to the area under the discrete charge period) in this discrete charge period 442 is less than the discrete charge periods of FIGS. 4A and 4B. Thus, the impedance may be reduced in comparison to the other charge signals, but less power is delivered to the battery cell 104 to charge the cell. The discrete charge period 422 of FIG. 4B provides a balance between the contrasting considerations of impedance and power delivery during charging of a battery cell.

To achieve the balance between the considerations of impedance and power delivery, a circuit controller 110 may monitor or measure the impedance at the battery cell 104 and adjust the shape, including any component thereof, of the discrete charge period in response. In some instances, rather than relying on discrete measurements of voltage and current, which may be used to obtain impedance characteristics or values, the system may estimate one or more of the measurements described above. For example, FIG. 5 illustrates a discrete charge period 501, which may be a part of a charge signal for charging a battery cell 104. The signal diagram 501 is similar to the discrete charge period 201 described above in relation to FIG. 2, including the indication of points along the discrete charge period (both for the voltage component 502 of the discrete charge period 501 and the current component 503 of the discrete charge period). For example, the circuit controller 110 may determine a voltage at point 520, point 512, etc. and a current at point 522, point 524, etc. These measurements may be utilized to determine the impedance of the battery cell 104 at various times along the discrete charge period. However, rather than discrete measurements at one or more of these points, the system may instead estimate one or more of the measurements at the indicated points.

For example, voltage V₁ may be measured at the transition point 520 of the voltage component between the leading edge portion of the discrete charge period 501 and the body portion of the discrete charge period. Current I₁ may similarly be measured at the transition point 522 for the current component of the discrete charge period. In a voltage-controlled system, the transition point 520 may be determined and the voltage measured accordingly based on the control of the voltage component—e.g., a measurement is made at the time when the voltage transitions from the leading edge to the constant body value. Since the current transition is not aligned with the voltage transition, the system cannot simply measure current at the same time it measures voltage at the transition point. Thus, accurately measuring the current component at the correct time to align with the transition may be difficult, and a measurement either earlier or later than the actual transition may result in some in accuracies in the estimation of the impedance at the battery cell. Thus, in one possible implementation, the circuit controller 110 may estimate one or more of the voltage, current, or time measurements discussed herein to improve the efficiency or accuracy of the impedance determinations at the battery cell 104.

In one implementation, the circuit controller 110 may obtain the rate of change of the voltage measurements of the voltage component 502 and the rate of change of the current measurements of the current component 503 during the leading edge portion of the charge signal. The rate of change of the components may correlate to the slope of the corresponding charge signal components. Through the monitoring of the rate of change of the components, the point along the leading edge at which the slope or the rate of change is the maximum may be determined. For example, the maximum slope point 509 for the voltage component of the discrete charge period 501 may be obtained by measuring the voltage along the curve 502 to find the transition between an increasing rate of change and a decreasing rate of change. This inflection point 509 may be the maximum slope of the voltage curve 502. In a similar manner, the inflection point 507 for the current component 503 of the discrete charge period 501 may also be determined. With the point 518 at which the waveform is begun and the inflection points 507, 509 of the voltage component 502 and the current component 503 determined, the system may estimate a time at which each respective component transitions from the leading edge portion to the body portion of the discrete charge period. In particular, as the leading edge of the discrete charge period is a sinusoidal shape, the inflection points 507 and 509 may be assumed to occur at the midpoint of the leading edge of the discrete charge period 501. Thus, the circuit controller 110 may then estimate the transition point 522 or 520 from the leading edge to the body portion of the discrete charge period 501 as occurring at a point that is twice the duration from the initial point 518 to the midpoint 507 and 509 for the respective component of the discrete charge period. The circuit controller 110 may obtain a voltage measurement at point 520 and a current measurement at point 522 based on this estimation. The measurements of voltage and current at these estimated (or calculated) times may be used to determine Z_{R_EDGE} and/or Z_{IMG_EDGE}, or any other impedance measurement discussed herein.

In another example, the circuit controller 110 may accept a certain amount of error in the voltage and/or current measurement in calculating the impedance at the battery cell 104. For example, for a voltage-controlled discrete charge period 504, the circuit controller 110 may determine point 520 as the point at which the controlled voltage signal transitions from the leading edge, sinusoidal signal to the constant voltage of the body portion. However, rather than estimating the corresponding transition point 522 for the current component 503 of the discrete charge period 501, the circuit controller 110 may obtain a current measurement at the time of transition point 520 or at some fixed time delay therefrom. Although some error in the impedance value at the battery cell 104 is present in the comparison of the voltage V₁ and a current measurement at the same time or a time thereafter due to the delay in the current component 503 response, such an error may be acceptable by the circuit controller 110 when measuring the impedance at the battery cell 104. A similar approach may be utilized for current-controlled discrete charge periods by obtaining a voltage measurement at the point of transition of the current component from the leading edge portion to the body portion of the charge signal 501.

In still another instance, the voltage component of the discrete charge period 501 may not transition to the constant voltage of the body portion at the peak of the leading edge portion. Rather, as shown in FIG. 6A, the voltage component 602 may be controlled to continue the sinusoidal shape until the current component 603 reaches the apex of the leading edge portion. More particularly, the leading edge portion of the discrete charge period 601 may include a single harmonic, sinusoidal shape, such that the current portion 603 following the voltage portion is a similar sinusoidal shape. Because the discrete charge period 601 is a single harmonic, the time at which the apex of the current portion 603 of the discrete charge period 601 occurs may be accurately determined and the current I₁ at point 622 may be measured at the apex of the current portion of the leading edge. Following the determination of the time at which point 622 occurs, the voltage portion 604 may be defined such that it transitions from an initial downward portion of the sinusoidal harmonic to a constant voltage for the body of the discrete charge period 601. Doing so, may cause a very low impedance at this point and may cause the body portion of the signal to be applied at a very low impedance. The low impedance being exemplified by the little or no separation between the voltage and current components of the signals in the body portion of the discrete charge period.

In another instance illustrated in FIG. 6B, the voltage portion 616 may be controlled to take on a Bessel Function shape of diminishing sinusoidal waves for the body portion of the discrete charge period 610. Controlling the voltage component 616 into a Bessel Function shape may reduce high harmonics that may be introduced in the transition from the sinusoidal leading edge to the constant voltage portion at point 620. However, the use of the Bessel Function signal shape may also reduce the power delivered to the battery cell 104. Through the use of the continued sinusoidal leading edge voltage signal 616, an accurate determination of the apex 620 of the current portion 614 of the leading edge may be obtained for a more accurate measurement of I₁. Further, the control circuit 110 may control the voltage portion of the discrete charge period 616 as a Bessel Function to occur at less than each of the discrete charge periods to the battery cell 104. For example, a Bessel Function discrete charge period 610 may occur once out of every 100 or 1000 discrete charge periods to obtain an accurate reading of I₁ without reducing the power delivered at every discrete charge period.

In yet another instance and returning to FIG. 5, the circuit controller 110 may calculate cumulative impedance for each portion or section of the discrete charge period 501. For example, the circuit controller 110 may obtain a voltage measurement and a current measurement for several points along the leading edge portion of the discrete charge period. Corresponding voltage measurements and current measurements may occur at the same time. Thus, although the current component 503 of the discrete charge period 501 is trailing the voltage component 502, the circuit controller 110 may obtain simultaneous voltage and current measurements to estimate a real impedance value or impedance magnitude value at the several points along the leading edge curve of the discrete charge period 501. The impedance measurements at the various points along the leading edge may be summed to obtain a real impedance for the battery cell 104 during the entirety of the leading edge of the discrete charge period 501. In a similar manner, horizontally corresponding measurements of the two components 502, 503 may be obtained at various points along the leading edge of the discrete charge period 501. For example, the time between the occurrence of a particular voltage measurement and a corresponding current measurement may be obtained and an imaginary impedance value or impedance phase shift value for the battery cell 104 may be approximated from the measured values and time delay. A series of such imaginary impedance measurements may be summed to obtain a cumulative imaginary impedance for the battery cell 104 during the leading edge portion. Similar approaches may be performed for the body portion of the discrete charge period 501. The summations of the impedances of the battery cell 104 for the portions of the discrete charge period 501 may then be utilized to adjust the shape of future waveforms, as explained above.

In another example, the circuit controller 110 may analyze other features of the leading edge of the discrete charge period 501 and adjust future discrete charge periods in response. In particular, the circuit controller 110 may measure various points of the voltage component 502 and/or the current component 503 and compare the measurements to an example sine wave shape corresponding to the selected harmonic of the leading edge. As controlled by the circuit controller 110, the leading edge portion of the discrete charge period 501 may include abnormalities from a true sine wave shape. These abnormalities may be detected by a comparison of the generated discrete charge period 501 to the example sine wave and adjustment to a future discrete charge period may be made by the circuit controller 110 to better approximate the example sine wave signal. Such adjustments may be made to the voltage component 502 and/or the current component 503 of the discrete charge period 501 to better approximate the example sine curve.

As mentioned above, hundreds or thousands of measurements of the voltage and current portion of the charge signal may be obtained and analyzed via a digital processing system to shape the discrete charge period of the battery cell 104. In one particular example, points of the discrete charge period may be analyzed via domain transformation between time and frequency. In this example, the edges and body of the discrete charge period may not be defined as described above based on the measured impedance values. Instead, the discrete charge period may be controlled to take on a more arbitrary shape. Further, the rest period between discrete charge periods may be subject to the same analysis and distinctions between edge, body and rest periods may further erode.

In this example, voltage and current discrete charge periods (for a single period or multiple, averaged periods) may be measured in the time domain. Fast Fourier transform (FFT), or many other types of transformations, may be used to convert the measured time domain data to corresponding data in the frequency domain. In some instances, the selection of the type of transformation used may depend upon the format of the data, the type of noise and signal to noise ratio in the data, or the processor type of the circuit controller 110. One or more of these factors may allow some transforms to process faster or better than FFT. By transforming the discrete charge period data into the frequency domain, the magnitudes of individual harmonics within the discrete charge period may be exposed and manipulated to generate a multi-harmonic discrete charge period. In particular, each harmonic obtained from the transform of the discrete charge period may be independently analyzed, comparing voltage and current, to determine the independent contribution of each to impedance, power, peak voltage and current at the battery cell 104. For example, harmonics with relatively high impedance qualities at the battery cell 104 can be reduced in magnitude and others may be increased to produce a more ideal collection of harmonics of the discrete charge period 201. The modified transforms may then be inversely transformed back into the time domain, yielding a new discrete charge period with a lower overall impedance that may be applied as an improved discrete charge period. Further, in some instances, gating may be performed on the transformed discrete charge period to independently analyze individual sections of the discrete charge period, with each inversely transformed section rejoined to produce an improved form of the complete discrete charge period.

More particularly, the process of gating the transformed discrete charge period may include transforming only a portion of the time domain data to the frequency domain for independent analysis. For example, the discrete charge period may be divided into fifths and each fifth independently evaluated along with or in lieu of whole wave analysis. This is especially useful when sections of the wave are heavily multi-modal in magnitude or harmonic content, such as body vs rest period. The gating process may provide a more accurate estimation of an imaginary and real component of impedance, and may be useful in analyzing/reducing oscillations that can occur in the discrete charge period due to the impedance of the battery cell 104. Gating may also provide a foundation for a mechanism of adjusting the total period of the discrete charge period. For example, a single gated section of the discrete charge period may include a portion of the rest period and adjustments to the harmonics of the section may reduce or extend the effective period.

In addition to the calculations discussed above, other calculations may also be determined based on measurements obtained from the charge waveform. For example, multiple measurements of both the voltage waveform 202 and/or the current waveform 207 for multiple discrete charge periods of the waveform may be obtained and summed to generate an average impedance value for the multiple discrete charge periods. In one example, a total impedance of the leading edge portion of the multiple discrete charge periods with elapsed time Δt may be determined by:

$$\sum \frac{{V}_{1}}{{I}_{0}} * Δ t$$

Similarly, a total impedance of the body portion of the multiple discrete charge periods with elapsed time Δt may be determined by:

$$\sum \frac{{V}_{2}}{{I}_{1}} * Δ t$$

Other impedance calculations may also be determined from measurements obtained from multiple discrete charge periods or other portions of the charge waveform. For example, a maximum impedance for the body portion 203 of one or more discrete charge periods may be determined by:

$$Maximum ( \frac{{V}_{i}}{{I}_{i} * Δ t} )$$

for measured values (i) between the start of the body portion to the end of the body portion. A delta mean of the impedance for the body portion 203 of one or more discrete charge periods may be determined by:

$$\sum \frac{Bodyend {V}_{N}}{{BodystartI}_{N} * Δ t} / ( Bodyend - Bodystart )$$

Further, a delta minimum of the impedance for the body portion 203 of one or more discrete charge periods may be determined by:

$$Minimum ( \frac{{V}_{i}}{{I}_{i} * Δ t} )$$

for measured values (i) between the start of the body portion to the end of the body portion.

In some instances and in response to noise that may be present in the discrete charge period, impedance measurements may be approximated from one or more centroid calculations. More particularly, the different portions of the discrete charge period, such as discrete charge period 201 of FIG. 2, may include a centroid or arithmetic mean position of all of the points in the corresponding portion. This may aid in reducing noise in the impedance calculations discussed above. In one example, a centroid for the leading edge portion of the discrete charge period 201 and a centroid for the body portion of the discrete charge period may be calculated. These centroid points may be utilized by the circuit controller 110 as the impedance measurements for those portions of the discrete charge period and may be minimized to improve the efficiency of the applied discrete charge period to the battery cell 104. For example, the centroid of the voltage component 202 of the leading edge portion of the discrete charge period 201 may be calculated from:

$${\overline{V}}_{E D G E} = \frac{{\int }_{V \_ min}^{V \_ max} V * ( {t}_{1} - {t}_{0} ) dV}{Total Edge Area} ;$$

$${\overline{t}}_{{V}_{E D G E}} = \frac{{\int }_{t 0}^{t 1} t * ( {V}_{M A X} - {V}_{MIN} ) dt}{Total Edge Area}$$

with t₁ corresponding to point 222 and to corresponding to point 218 and the maximum and minimum values corresponding to the maximum and minimum measured values within the leading edge portion. The centroid of the current component 207 of the leading edge may be calculated from:

$${\overline{A}}_{E D G E} = \frac{{\int }_{A \_ min}^{A \_ max} A * ( {t}_{1} - {t}_{0} ) dA}{Total Edge Area} ;$$

$${\overline{t}}_{A \_ EDGE} = \frac{{\int }_{t 0}^{t 1} t * ( {A}_{M A X} - {A}_{MIN} ) dt}{Total Edge Area}$$

In a similar manner, centroid of the voltage component of the body portion 203 of the discrete charge period 201 may be calculated from:

$${\overline{V}}_{B O D Y} = \frac{{\int }_{V \_ min}^{V \_ max} V * ( {t}_{2} - {t}_{1} ) dV}{Total Body Area} ;$$

$${\overline{t}}_{V \_ BODY} = \frac{{\int }_{t 1}^{t 2} t * ( {V}_{M A X} - {V}_{MIN} ) dt}{Total Body Area}$$

with t₀ corresponding to point 222 and ti corresponding to point 212 and the maximum and minimum values corresponding to the maximum and minimum measured values within the leading edge portion. The centroid of the current component 204 of the body portion may be calculated from:

$${\overline{A}}_{B O D Y} = \frac{{\int }_{A \_ min}^{A \_ max} A * ( {t}_{2} - {t}_{1} ) dA}{Total Body Area} ;$$

$${\overline{t}}_{A \_ BODY} = \frac{{\int }_{t 1}^{t 2} t * ( {A}_{M A X} - {A}_{MIN} ) dt}{Total Body Area}$$

From the centroid points calculated, real and imaginary impedance values for the leading edge portion may be calculated from:

$${Z}_{R \_ EDGE}^{c} = \frac{{\overline{V}}_{E D G E}}{{\overline{A}}_{E D G E}} ; {Z}_{I \_ EDGE}^{c} = \frac{{\overline{t}}_{V \_ EDGE}}{{\overline{t}}_{A \_ EDGE}}$$

and centroid impedance modulus for the leading edge may be calculated from:

Z_{M_EDGE}^{c}=\sqrt{Z_{R_EDGE}^{c}²+Z_{I_EDGE}^{c}²}

Real and imaginary impedance values for the body portion may be calculated from:

$${Z}_{R \_ BODY}^{c} = \frac{{\overline{V}}_{BODY}}{{\overline{A}}_{BODY}} ; {Z}_{I \_ BODY}^{c} = \frac{{\overline{t}}_{V \_ BODY}}{{\overline{t}}_{A \_ BODY}}$$

and centroid impedance modulus for the body portion may be calculated from:

Z_{M_BODY}^{c}=\sqrt{Z_{R_BODY}^{c}²+Z_{I_BODY}^{c}²}

Although discussed above as calculating real and imaginary impedance values for the leading edge portion of the discrete charge period, it should be appreciated that the centroid calculations for the leading edge may not generally be utilized by the circuit controller 110 to determine the harmonic of the leading edge as such centroid calculations are arithmetic mean positions of all of the points in the corresponding portion. Rather, in some implementations, the centroid equations discussed above for the leading edge may be utilized by the circuit controller 110 to verify an estimate of the impedance at the leading edge, particularly for discrete charge periods that may include noise within the signal. Utilizing the centroid calculations to verify other estimations of the leading edge portion of the discrete charge period may improve the accuracy of such estimations used to shape additional discrete charge periods. In still other instances, the estimated impedances obtained via one or more of the methods described herein and the estimated impedances based on the centroid calculations may be provided with a particular weighted value. The weighted values assigned to the various methods for obtaining the impedance estimates may be based, in some instances, on an amount of noise in the discrete charge period.

The above centroid equations utilize a continuous integral function to determine the centroid of the waveform portions. In another example, a centroid of a polygon approximating the shape of the portions of the charge waveform 201 may be calculated. It is noted that other methods for calculating a centroid depending upon an orientation of the polygon or ‘shape’ relative to a preferred axis may also be utilized. Rather, the equations provided below are simply an example of one collection of centroid calculations that may be performed. For example, the equation above to determine the centroid of the voltage component 202 of the leading edge portion of the discrete charge period 201 may be calculated as follows:

$${\overline{V}}_{E D G E} = \frac{{\int }_{V \_ min}^{V \_ max} V * ( {t}_{1} - {t}_{0} ) dV}{Total Edge Area} \sim \frac{1}{6 * {Area}_{Vedge}} * {\sum }_{PolygonStart}^{PolygonEnd} ( {V}_{N} + {V}_{N + 1} ) * ( {t}_{N} {V}_{N + 1} - {t}_{N + 1} {V}_{N} )$$

$$where$$

$${Area}_{Vedge} = \frac{1}{2} * {{\sum }_{PolygonStart}}^{PolygonEnd} ( {t}_{N} {V}_{N + 1} - {t}_{N + 1} {V}_{N} )$$

Similarly, the equation to determine the centroid of the time of the voltage component 202 of the leading edge portion of the discrete charge period may be calculated as follows:

$${\overline{t}}_{{V}_{EDGE}} = \frac{{\int }_{t 0}^{t 1} t * ( {V}_{M A X} - {V}_{MIN} ) dt}{Total Edge Area} ∼ \frac{1}{6 * A r e {a}_{Vedge}} * {\sum }_{PolygonStart}^{PolygonEnd} ( {t}_{N} + {T}_{N + 1} ) * ( {t}_{N} {V}_{N + 1} - {t}_{N + 1} {V}_{N} ) .$$

The centroid of the current component 207 of the leading edge may be calculated from:

$${\overline{A}}_{E D G E} = \frac{{\int }_{A \_ min}^{A \_ max} A * ( {t}_{1} - {t}_{0} ) dA}{Total Edge Area} \sim \frac{1}{6 * {Area}_{Iedge}} * {\sum }_{PolygonStart}^{PolygonEnd} ( {I}_{N} + {I}_{N + 1} ) * ( {t}_{N} {I}_{N + 1} - {t}_{N + 1} {I}_{N} )$$

$$where$$

$${Area}_{Iedge} = \frac{1}{2} * {{\sum }_{PolygonStart}}^{PolygonEnd} ( {t}_{N} {I}_{N + 1} - {t}_{N + 1} {I}_{N} )$$

Similarly, the equation to determine the centroid of the time of the current component of the leading edge portion 211 of the discrete charge period 202 may be calculated as follows:

$${\overline{t}}_{A \_ EDGE} = \frac{{\int }_{t 0}^{t 1} t * ( {A}_{M A X} - {A}_{MIN} ) dt}{Total Edge Area} \sim \frac{1}{6 * {Area}_{Iedge}} * {\sum }_{PolygonStart}^{PolygonEnd} ( {t}_{N} + {t}_{N + 1} ) * ( {t}_{N} {I}_{N + 1} - {t}_{N + 1} {I}_{N} ) .$$

In a similar manner, centroid of the voltage component of the body portion 203 of the discrete charge period 201 may be calculated from:

$${\overline{V}}_{BODY} = \frac{{\int }_{V \_ min}^{V \_ max} V * ( {t}_{2} - {t}_{1} ) dV}{Total Body Area} \sim \frac{1}{6 * {Area}_{Vbody}} * {\sum }_{PolygonStart}^{PolygonEnd} ( {V}_{N} + {V}_{N + 1} ) * ( {t}_{N} {V}_{N + 1} - {t}_{N + 1} {V}_{N} )$$

$$where$$

$${Area}_{Vbody} = \frac{1}{2} * {{\sum }_{PolygonStart}}^{PolygonEnd} ( {t}_{N} {V}_{N + 1} - {t}_{N + 1} {V}_{N} )$$

The equation to determine the centroid of the time of the voltage component 202 of the body portion of the discrete charge period may be calculated as follows:

$${\overline{t}}_{V \_ BODY} = \frac{{\int }_{t 1}^{t 2} t * ( {V}_{M A X} - {V}_{MIN} ) dt}{Total Body Area} ∼ \frac{1}{6 * A r e {a}_{Vbody}} * {\sum }_{PolygonStart}^{PolygonEnd} ( {t}_{N} + {t}_{N + 1} ) * ( {t}_{N} {V}_{N + 1} - {t}_{N + 1} {V}_{N} ) .$$

The centroid of the current component 207 of the body portion 203 of the discrete charge period 201 may be calculated from:

$${\overline{A}}_{BODY} = \frac{{\int }_{A \_ min}^{A \_ max} A * ( {t}_{2} - {t}_{1} ) dA}{Total Body Area} \sim \frac{1}{6 * {Area}_{Ibody}} * {\sum }_{PolygonStart}^{PolygonEnd} ( {I}_{N} + {I}_{N + 1} ) * ( {t}_{N} {I}_{N + 1} - {t}_{N + 1} {I}_{N} )$$

$$where$$

$${Area}_{Ibody} = \frac{1}{2} * {{\sum }_{PolygonStart}}^{PolygonEnd} ( {t}_{N} {I}_{N + 1} - {t}_{N + 1} {I}_{N} )$$

Similarly, the equation to determine the centroid of the time of the current component of the leading edge portion 211 of the discrete charge period 202 may be calculated as follows:

$${\overline{t}}_{A \_ BODY} = \frac{{\int }_{t 1}^{t 2} t * ( {V}_{M A X} - {V}_{MIN} ) dt}{Total Body Area} ∼ \frac{1}{6 * A r e {a}_{Ibody}} * {\sum }_{PolygonStart}^{PolygonEnd} ( {t}_{N} + {t}_{N + 1} ) * ( {t}_{N} {I}_{N + 1} - {t}_{N + 1} {I}_{N} ) .$$

As above, real and/or imaginary impedance values for the leading edge portion may be calculated from the centroid points calculated, such as:

$${R}_{E D G E} = \frac{{\overline{V}}_{E D G E}}{{\overline{A}}_{E D G E}}$$

for a resistance calculation of the leading edge portion and:

$${TR}_{E D G E} = \frac{{\overline{t}}_{V \_ EDGE}}{{\overline{t}}_{A \_ EDGE}}$$

for a time ratio edge centroid of the leading edge.

Similarly, real and/or imaginary impedance values for the body portion may be calculated from the centroid points calculated, such as:

$${R}_{B O D Y} = \frac{{\overline{V}}_{B O D Y}}{{\overline{A}}_{B O D Y}}$$

for a resistance calculation of the body portion and:

$${TR}_{B O D Y} = \frac{{\overline{t}}_{V \_ BODY}}{{\overline{t}}_{A \_ BODY}}$$

for a time ratio edge centroid of the leading edge.

Some battery charging environments may include components for which the above calculations and operations may be limited. For example, the circuit controller 110 for the charging circuit 100 may include a processing device for which fast and multi-variable calculations may not be available. In such instances, measurements taken over multiple periods of time may be obtained by the circuit controller 110 and combined by the circuit controller to measure or estimate a characteristic or parameters of the battery cell 104 of the charging circuit. One example of obtaining measurements of aspects of the battery cell 104 and combining such measurements is illustrated in FIGS. 7-8B. More particularly, FIG. 7 is a schematic diagram illustrating a circuit for charging a battery based on a measured impedance value in accordance with one embodiment, FIG. 8A is a signal diagram of measured currents into a battery cell in blocks of time, and FIG. 8B is a signal diagram of measured voltages across a battery cell in blocks of time. As explained in more detail below, the charge circuit may obtain current and voltage measurements at the battery 104 at different blocks of time and combine aspects of the measurements to estimate characteristics of the battery cell 104, such as an estimated power at the battery or one or more impedance parameters of the battery. This method for processing the measurements may reduce the processing burden on a circuit controller 110 at any one time while still obtaining the impedance parameters for use in shaping a charge waveform for the battery.

As noted above, FIG. 7 is a schematic diagram illustrating a circuit 700 for charging a battery 704 based on measurements of the battery obtained over a period of time. The circuit 700 may include elements described above with reference to the charging circuit 100 of FIG. 1A, including power supply 702, circuit controller 706, and battery 704. As explained above, the circuit controller 706 may provide one or more control signals 730, 732 to elements of the circuit, e.g., circuit 724, to shape a current or voltage signal from the power supply 702 to charge the battery cell 704. While discussed in the context of charge, aspects of the system and method discussed may also apply to discharge control. In addition, while the term charge or discharge signal may be used, in some situations a probe signal intended to obtain current or voltage responses, from which impedance characteristics may be determined, may be applied to the battery and such probe signal may be considered a charge or discharge signal depending on whether some energy is being applied to or from the battery respectively. The circuit controller 706 may be implemented through a Field Programmable Gate Array (FPGA) device, a microcontroller, an Application-Specific Integrated Circuit (ASIC), or any other programmable processing device, with the particularly identified devices providing possibly more cost-effective performance in some applications where additional processing capabilities are limited or unnecessary and cost margins are important. In one implementation, the circuit controller 706 may include a charge signal shaping generator 710 functional block of the controller, the generator to determine the shape of the charge signal to be applied to the battery cell 704. The charge signal shaping generator 710 of the circuit controller 706 may, in some instances, receive measurements of characteristics of the battery cell from a battery cell current measurement circuit 708 and/or a battery cell voltage measurement circuit 726 for use in determining impedance, which is in turn used to determine the shape of the charge signal. In one particular implementation, the circuit controller 706 may include components utilized to receive and store the measurements of the battery cell characteristics for combination and calculation of an impedance parameter associated with the battery 704. In another implementation, the circuit controller 706 may utilize the stored measurements of the battery characteristics to calculate or estimate a power level of the battery 704, among other parameters of the battery.

As mentioned, the circuit 700 may include one or more components to shape a charge signal for charging a battery 704. In the particular implementation shown, the circuit 700 may include a first switching element, e.g., transistor 712, and a second switching element, e.g., transistor 714, connected in series to an output 734 of the power supply 702. The first transistor 712 may receive an input signal, such as pulse-width modulation (PWM) control signal 730, from the signal shaping generator 710 to operate the first transistor 712 as a switching device or component. In general, the first transistor 712 may be any type transistor, e.g., a FET, or any type of controllable switching element for controllably connecting a first inductor 716 to the output 734 of the power supply 702. For example, the first transistor 712 may be a FET with a drain node connected to the first inductor 716, a source connected to the power supply 702, and a gate receiving the control signal 730 from the circuit controller. The control signal 730 may be provided by the circuit controller 706 to control the operation of the first transistor 712 as a switch that, when closed, connects the first inductor 716 to the power supply 702 such that the charge signal from the power supply flows through the first inductor 716. The second transistor 714 may receive a second input signal 732 and may also be connected to the drain of the first transistor 712 at node 736. In some instances, the second input signal 732 may be a PWM signal opposite of the first control signal 730 to the first transistor 712. Thus, when the first transistor 712 is closed to connect the first inductor 716 to the power supply 702, the second transistor 714 is open. When the first transistor 712 is open, conversely, the second transistor 714 is closed, connecting node 726 and the first inductor 716 to ground. Generally speaking, a sequence of charge signals is provided at node 736, which when applied to the inductor 716, and other components of circuit 724 depending on any given implementation, may shape various aspects of any charge signal applied to the battery 704. In some instances, a leading edge of the charge signal, as well as other aspects of the charge signal, is defined to approximate a portion of a sinusoid at a frequency based on the impedance discussed herein. Although the first control signal 730 and the second control signal 732 are described herein as opposing signals to control the transistors into opposing states, other techniques for controlling the switching elements 712, 714 may also be implemented with the circuit 700. The inductor value, the capacitor value, the time and frequency of actuating the transistors, and other factors can be tailored to generate a waveform and particularly a waveform with controlled harmonics to the battery for charging the same.

In addition to the first inductor 716, other components may be included in the circuit 700, collectively referred to as a “filter” 724 portion of the circuit. In particular, the circuit 700 may include a first capacitor 722 connected between the output of the power supply 734 and ground. A second capacitor 720 may be connected between the first inductor 716 (at node 738) and ground. A second inductor 718 may be connected between node 738 and an anode of the battery cell 704. The filter 724 of the circuit 700 may operate, in general, to define the shape of the charge signal and/or prevent rapid changes to the charge signal applied to the battery cell 704. For example, upon closing of the first transistor 712 based on control signal 730, first inductor 716 and second inductor 718 may prevent a rapid increase in current transmitted to the battery cell 704. Such rapid increase in current may damage the battery cell 704 or otherwise be detrimental to the life of the battery cell. Moreover, the inductor may shape the waveform applied to the battery, and control of the signal applied to the inductor may provide for controlled shaping of the waveform. In another example, capacitor 720 may store energy from the power supply 702 while first transistor 712 is closed. Upon opening of the first transistor 712, the capacitor 720 may provide current to the battery cell 704 through second inductor 718 to resist an immediate drop of current to the battery and may similarly be used to controllably shape the waveform applied to the battery.

It should be appreciated that more or fewer components may be included in charge circuit 700. For example, one or more of the components of the filter circuit 724 may be removed or altered as desired to filer the charge signal to the battery cell 704. Many other types of components and/or configurations of components may also be included or associated with the charge circuit 700. Rather, the circuit 700 of FIG. 7 is but one example of a battery cell charging circuit 700 and the techniques described herein for analyzing impedance for generating or otherwise determining control signals 730, 732 for shaping a charge signal.

As described above, the signal shaping generator 710 of the circuit controller 706 may control the shape of the charge signal based on feedback measurements of the battery 704. As such, circuit 700 may include a current measurement circuit 708 to measure the current into the battery cell (such as measured using a small resistor 728 in series with the application of the charge current to the battery) and a voltage measurement circuit 726 measuring the voltage across terminals of the battery 704. These measurements may be provided to the signal shaping generator 710 which may, in turn, control, via control signals 730, 732, the first transistor 712 and the second transistor 714 to adjust the shape of the charge signal to the battery 704. In other words, the signal shaping generator 710 may sculpt or otherwise define a shape of a charge signal transmitted to the battery cell 704 based on the measurements received from current measurement circuit 708 and/or voltage measurement circuit 726, as explained in more detail below.

The signal shaping generator 710 may process measurements obtained by the current measurement circuit 708 at a different time than measurements obtained by the voltage measurement circuit 726 to calculate or estimate an impedance parameter of the battery 704. To process the battery cell characteristic measurements in this manner, the circuit controller 706 may include additional measurement processing components, such as multiplexer device A 740, analog to digital converter 742, multiplexer device B 744, and one or more memory components (such as memory component A 746 and memory component B 748). More or fewer components may also be included with the circuit controller 706 and some components maybe combined into a single component, such as memory devices 746, 748 may be a single memory device or may be memory locations within a separate memory structure. The operations of the various components of the circuit controller 706 is discussed in more detail below.

In some instances, the circuit controller 706 may control one or more components of the circuit 700 to utilize measurements of battery characteristics taken at different times to determine or estimate one or more impedance parameters of the battery 704 in response to a charge signal applied to the battery cell. For example, FIG. 8A illustrates a current component 800 of a series of charge energy packets defining a charge waveform provided to the battery 704, which may be based on control of the charge circuit 700 components by the circuit controller 710. The current component 800 is shown on a graph with current values along the y-axis 802 and time along the x-axis 824. In general, the charge waveform includes a current component 800 that repeats over multiple blocks of time. In this example, there are three energy packets 812, 814, 816 of differing widths each with a harmonically tuned or otherwise shaped leading edge, with the three packets repeating the time blocks. The signal diagram illustrates the current component 800 of the charge waveform over four blocks of periods of time, namely period block A 804, period block B 806, period block C 808, and period block D 810. The period duration P_{A}-P_{D} for each of the time blocks may be same duration or take the same amount of time. In addition, the circuit controller 706 may be programmed or otherwise configured to generate a repeating charge waveform, with each period of the repeating charge waveform occurring during one of the period durations. For example and as shown in FIG. 8A, the circuit controller 706 may control other components of the charge circuit 700 to generate a first charge signal 812, followed by a second charge signal 814, followed by a third charge signal 816 during block A 804 of the charge waveform. Each of the charge signals 812-816 may have a different duration than the other charge signals within the same block 804. Thus, charge signal 812 may have a first duration, charge signal 814 may have a second duration different than the first duration, and charge signal 816 may have yet a third duration. The various example charge waveforms may vary depending on impedance among other things.

The same or similar charge waveform pattern may occur for each time block 804-810 of the charge waveform. For example, the same charge signals 812-816 may be repeated during time block B 806, time block C 808, and time block D 810. Although only four time blocks are illustrated in FIG. 8A, it should be appreciated that the charge waveform may repeat any number of times during a charging process of the battery cell 704. In any given time block, there may be more or fewer charge signals, and the time duration of any block or charge waveform may vary. The shape and number of charge waveforms may also vary from block to block. Also, each charge signal may correspond to a charge signal in the previous or multiple previous time blocks. For example, charge signal 818 of time block C 808 may be similar or the same as charge signal 812 of time block A 804, charge signal 820 of time block C may be similar or the same as charge signal 814 of time block A, and charge signal 822 of time block C may be similar or the same as charge signal 816 of time block A. In general and in the illustrated example, each of the signals within a block of time 804-810 is the same or similar to a previous block such that the charge waveform comprises a repeating pattern of charge signals. It should be appreciated that the signals are shown with shaped leading edges, which are illustrative of harmonically tuned shaped signal blocks. For example, any given block may include specific harmonic components, and the leading edges of each may also be shaped. These harmonically tuned blocks may be repeated within each time block 804-810. In some instances, a square or otherwise sharp edge pulse may be used with fairly low energy content and for a brief duration for the purpose of assessing impedance to present harmonics.

The signal diagram of FIG. 8A illustrates the charge component 800 of the charge signal applied to charge the battery cell 704. Similarly, FIG. 8B illustrates a signal diagram of measured voltages 850 across a battery cell in blocks of time for determining impedance values at the battery cell in accordance with one embodiment. Similar to the current component 800 discussed above, the voltage component 850 is illustrated on a graph with voltage values along the y-axis 852 and time along the x-axis 868. The voltage component 850 of the charge waveform repeats over the same multiple blocks of time, namely period block A 854, period block B 856, period block C 858, and period block D 860. The voltage component 850 of the charge waveform includes generally the same shape as the current component 800 such that the voltage component is a repeating signal for each time block 854-860. As such, a different shape of the charge waveform would be reflected in both the current component 800 and the voltage component 850.

In addition to the current component 800 of the charge waveform, FIG. 8A illustrates a measured current into the battery cell 704 as obtained from the current measurement circuit 708 in response to the charge waveform. For example, during charge signal 812, the current measurement circuit 708 may obtain the current measurement of I₁. Similarly, during charge signal 814, the current measurement circuit may obtain the current measurement of I₂ and, during charge signal 816, the current measurement circuit may obtain the current measurement of I₃. In a similar manner, during charge signal 818 of time block C 818, the current measurement circuit 708 may obtain the current measurement of I₄, the current measurement of I₅ during charge signal 820, and the current measurement of I₆ during charge signal 822. Current measurements may also be made during the charge signals of time block B 806 and time block D 810 by the current measurement circuit 706, although not illustrated in the signal diagram of FIG. 8A.

In a similar manner, FIG. 8B illustrates a measured voltage across the battery cell 704 as obtained from the voltage measurement circuit 726 in response to the charge waveform. For example, during charge signal 862 of time block B 856, the voltage measurement circuit 726 may obtain the voltage measurement of V₁, the current measurement circuit may obtain the voltage measurement of V₂, and the voltage measurement of V₃ during charge signal 866. Voltage measurements may also be made during the charge signals of time block A 854, time block C 858, and time block D 860 by the voltage measurement circuit 726, although not illustrated in the signal diagram of FIG. 8B.

The signal diagrams illustrated in FIGS. 8A and 8B are one example of current and voltage measurements that may be obtained through circuit 700, although other examples may be implemented or performed by the circuit. For example, the circuit 700 may be configured to obtain voltage measurements during block A of the charge waveform and current measurements during block B. In another example, the circuit 700 may be configured to obtain both voltage and current values in any block of the charge waveform. Still further, the obtained measurements are not required to alternate between subsequent blocks. For example, voltage measurements may be obtained for a series of consecutive blocks (such as block A and block B) and current measurements may be obtained for one or more subsequent blocks (such as block C and block D). Further still, the measurements may be obtained in any order. For example, a voltage measurement may be obtained in time block A, followed by a current measurement in time block B and time block C, with another voltage measurement obtained in time block D. In general, any battery cell characteristic may be measured in any time block of the charge waveform and stored in a memory device 746, 748. Such measurements may be obtained in any order or sequence to provide processing flexibility to the circuit controller 706 in determining or estimating an operational parameter of the battery cell 704.

In addition, although discussed herein as measuring a current into the battery cell 704 (utilizing the current measurement circuit 708) and measuring a voltage across the battery cell (utilizing the voltage measurement circuit 726), any battery cell characteristic may be measured and stored by the circuit controller 706 for use in determining a charge waveform shape. For example, other measurement circuits or devices (such as a power measuring device, impedance measuring device, etc.) may be included in circuit 700 and outputs from the other devices may be provided to the circuit controller 706, either in addition to the current and/or voltage measurements or in place of the current and/or voltage measurements. The additional battery characteristic measurements may be obtained over any number of time blocks as described herein, including alternating time blocks or in consecutive time blocks. Further, determination or estimation of the battery cell characteristic may include any number of the obtained measurements used to generate any number of battery cell characteristics that may be used to shape a charge waveform.

As illustrated in the circuit 700 of FIG. 7, the current measurement circuit 708 and the voltage measurement circuit 726 may provide the obtained measurements to the circuit controller 706 for use in calculating or estimating an impedance or other operating characteristic of the battery cell 704. However, some circuit controllers 706 may lack the processing power to perform the calculations at the speed at which the measurements are being provided. Similarly, in some practical implementations, relatively more sophisticated and expensive processors may not be specified, and hence it becomes necessary to process measurements without such processors. Such circuit controllers 706 may be configured to execute one or more of the operations of the method 900 illustrated in FIG. 9. In particular, FIG. 9 is a flowchart illustrating a method for 900 determining an operating characteristic of a battery cell based on measurements of the battery cell taken at different time periods in accordance with one embodiment. One or more of the operations may be performed or executed by the circuit controller 706 of charging circuit 700, although other components of the charging circuit or in addition to the charging circuit may also perform one or more of the operations of the method 900. Such operations may be executed through a software program, one or more hardware components, or a combination of software and hardware components.

Beginning in operation 902, the circuit controller 706 may be configured to receive a measurement of first battery cell characteristic during a first period of the charge waveform. For example, the current measurement circuit 708 may obtain current measurement I₁ during charge signal 812 of time block A 804 and provide the current measurement to the circuit controller 706. The controller, in one possible arrangement, may poll or otherwise actively obtain the measurement from the current measurement circuit. In one instance, the controller 706 may access the current measurement I and it may be provided or transmitted to multiplexer device A 740 of circuit controller 706. Multiplexer device A 740 may be controlled by circuit controller 706 to receive the current measurement I₁ and provide passthrough of the measurement to analog-to-digital converter (ADC) 742. Control of multiplexer device A 740 to allow passthrough of the current measurement may prevent transmission of a value from voltage measurement circuit 726 to the ADC 742. The ADC 742 may convert the analog current measurement into a digital value. In addition, the circuit controller 706 may control multiplexer device B 744 to allow passthrough of the output of the ADC 742 to be stored in memory A 746. Memory A 746 may be any type of memory device and may, in some instances, operate as a first-in, first-out stack of measurement values. The circuit controller 706 may receive and store one or more such current measurements during a time block, such as block A 804. For example, current measurement I₂ during charge signal 814 and current measurement I₃ during charge signal 816 may also be provided and stored by the circuit controller 706 in memory A 746.

At operation 904, the circuit controller 706 may be configured to receive a measurement of a second battery cell characteristic during a second, later period of the charge waveform. For example, the voltage measurement circuit 726 may obtain voltage measurement V₁ during charge signal 862 of time block B 856 and provide the voltage measurement to the circuit controller 706. The voltage measurement V₁ may be provided along the same path as the current measurement, namely through multiplexer device A 740, ADC 742, and multiplexer device B 744 of circuit controller 706. The circuit controller 706 may provide one or more control signals to multiplexer device A 740, ADC 742, and multiplexer device B 744 to control the flow of the voltage measurement to memory device B 748 and, in some instances, prevent transmission of a value from current measurement circuit 708 to the ADC 742 during time block B 856. Memory B 748 may also be any type of memory device and may, in some instances, operate as a first-in, first-out stack of measurement values. The voltage measurement values may therefore be received during time block B 856, occurring after time block A 804 in which the current measurements were received and stored. The circuit controller 706 may also receive and store multiple voltage measurements during the time block, such as voltage measurement V2 during charge signal 862 and voltage measurement V₃ during charge signal 866.

In effect, controller through control of the multiplexor 740, the controller alternates between current and voltage measurements. The alternating current and voltage measurements, are fed through the ADC 742, and control of the second multiplexor 744 alternates storing the digital values of the current and voltage measurements in memory A (746) and memory B (748). In some instances, analog to digital conversion may occur at the measurement circuits, in which case the ADC 742 may not be used. In such a case, the digital measurements, through control of a single multiplexor may be alternately stored in the memory A and memory B. In such a case, it may be that only a single multiplexor is present in or as an input to the controller 706.

Through alternating access to the current and voltage measurements and similarly alternating storage of the values in the two memories, the measurement values are aligned in the memory for further processing to determine impedance or other values. For example, the system may first sample one or more current measurements from Block A and store the one or more values in memory A. The memories are described herein as distinct memory devices, but it should be recognized that the first memory and the second memory may be partitions of the same memory device. The system may then sample one or more voltage measurements from Block B, and store the one or more values in memory B. The Block A current measurement or measurements are stored in sequential memory locations. The Block B voltage measurement or measurements are stored in sequential memory locations. The memories A and B may be of the same size and type, and hence the current and voltage measurements are aligned in memory. In this way, when the controller accesses the memory A and memory B to perform a computation using the respective measurements, the respective measurements are automatically aligned by way of the access coordination, memory storage and arrangement. So, if three measurements are processed from each of Block A for current and then Block B for voltage, the first current value 11 is stored in a memory location of memory A, and the first voltage value V1 is stored in the same memory location of Memory B, and so on with respect to subsequent current and voltage measurements. As such, to obtain impedance using current measurement 11 as compared to voltage measurement V1, the system only need access the same memory location in each of memory A and B, and the correct comparative values will be automatically in the same memory locations by way of how the values are loaded in the respective memories.

FIG. 10 illustrates an example of interlacing voltage and current sampling, where the alternating voltage and current measurements may be alternately stored in the respective memories. Thus, one memory will have a sequence of voltage measurements and other memory will have a sequence of current measurements. In this example, a charge signal 1000, similar in shape to those described above with regard to FIG. 2 and otherwise, the system alternates between measurement and storage of discrete measurements of voltage and current. As such, referring back to FIGS. 8A and 8B, a block would comprise only a single measurement of current or voltage at a discrete point in time. Referring to FIG. 10, for example, in a first sampling window 1002, current measurements ISn are interlaced with voltage measurements VSn. As such, current measurement IS1 will be stored in a first memory and then voltage measurement VS1 will be stored in a second memory. Each of the respective measurements are stored in the same memory location of the respective memories as discussed elsewhere herein. The interlacing of the current and voltage measurements and respective storage may then proceed during the time of the first sampling window. Referring back to FIG. 2, the first sampling window covers a window time between when the harmonically tuned or otherwise shaped leading edge 209 (1009) transitions to the body portion 203 (1003).

In terms of determining impedance, the system compares voltage to current as discussed with regard to FIGS. 2-6. The system may also compute impedance using an average of the voltage measurements during a time window as compared to an average of the current measurements during the same time window, with the averaging computations shown in FIG. 10. In another example, the system may compute impedance using a maximum voltage value compared to a maximum current value of the measured voltage and current values during a time window, with the maximizing formulas also shown in FIG. 10.

As noted above, impedance may be computed at different times relative to application of the charge signal. In the example of FIG. 10, in addition to the sample window at the transition from the leading edge to the body portion, a second sample time window 1004 may be defined when the charge signal transitions to zero and/or a third sample time window 1006 may be defined during a rest period 1005 between charge signals. In one specific example, the third sample time window may be defined during a time immediately preceding a charge signal when the current to the battery has settled to zero, whether in response to a negative voltage blip (e.g., below the terminal voltage) or otherwise after the charge current at the end of a voltage signal transitions to zero amps.

In more detail and referring again to FIG. 9, in operation 906, the circuit controller 706 may obtain a measurement of the first battery cell characteristic from memory A 746 and a measurement of the second battery cell characteristic from memory B 748. In a FIFO or what might be more generally considered a circular buffer arrangement of the two memories, the respective measurement in each memory queue are present at the memory locations that the controller accesses to perform the computation. Continuing the above example, the circuit controller may therefore obtain current measurement I₁ from memory A 746 and voltage measurement V₁ from memory B 748. In a FIFO arrangement, the current measurement I1 and voltage measurement V2 become available at the same respective memory locations in the respective memories A and B. Although discussed as the current measurement being the first battery cell characteristic and the voltage measurement being the second battery cell characteristic, any battery cell characteristic may be obtained and stored at any time by the circuit controller 706. Further, the circuit controller 706 may, in some instances, average one or more of the received battery cell characteristic measurements prior to or after storage. For example, the circuit controller 706 may average current values I₁, I₂, and I₃ received during time block A 804 to determine an average current during the time block. Averaging may occur prior to loading the individual values in memory or after accessing values. In another example, circuit controller 706 may average measurement values from different time blocks, such as voltage value V₁ from time block B 856 and voltage V₄ from time block D 860. In general, the circuit controller 706 may average any number of measurement values from any number of time blocks either upon retrieving the values from the memory devices 746, 748 or prior to storage in the memory devices.

In operation 908, the circuit controller 706 may determine an estimated battery cell characteristic or value from the measurement values obtained from the memory 746, 748. For example, the circuit controller 706 may utilize the stored current values and voltage values to estimate an impedance parameter of the battery cell 704. In some instances, the obtained measurement values may be provided to the signal shaping generator 710 for use in generating control signals of the charging circuit 700. In other instances, the circuit controller 706 may calculate the estimated characteristic of the battery cell 704 from the stored measurement values and control the signal shaping generator 710 in response to the estimated characteristic. Regardless, the circuit controller 706 may shape a charge signal for the battery cell 704 through control of one or more components of the charge circuit 700 based on the estimated battery cell characteristic value determined from the stored measurement values. Further, the measurements may be measured during different blocks of a repeating charge signal to allow the circuit controller 706 to process the measurements at a speed for which the circuit controller is capable.

Although discussed above with reference to the square-wave charge signals of FIGS. 8A and 8B, the above descriptions may equally apply to less uniform charge waveforms. Rather, the charge waveform may comprise a repeating series of charge signals that may be of any shape and duration during which a current measurement and/or a voltage measurement may be obtained at the battery cell 704. In some instances, the current measurement circuit 708 may average a measured current over the entirety or a portion of a time block and/or the voltage measurement circuit 726 may average a measured voltage over the entirety of a portion of the time block.

FIG. 11 is a block diagram illustrating an example of a computing device or computer system 1100 which may be used in implementing the embodiments of the network disclosed above. In particular, the computing device of FIG. 11 is one embodiment of a controller that performs one of more of the operations described above. The computer system (system) includes one or more processors 1102-1106. Processors 1102-1106 may include one or more internal levels of cache (not shown) and a bus controller or bus interface unit to direct interaction with the processor bus 1112. Processor bus 1112, also known as the host bus or the front side bus, may be used to couple the processors 1102-1106 with the system interface 1114. System interface 1114 may be connected to the processor bus 1112 to interface other components of the system 1100 with the processor bus 1112. For example, system interface 1114 may include a memory controller 1118 for interfacing a main memory 1116 with the processor bus 1112. The main memory 1116 typically includes one or more memory cards and a control circuit (not shown). System interface 1114 may also include an input/output (I/O) interface 1120 to interface one or more I/O bridges or I/O devices with the processor bus 1112. One or more I/O controllers and/or I/O devices may be connected with the I/O bus 1126, such as I/O controller 1128 and I/O device 1130, as illustrated.

I/O device 1130 may also include an input device (not shown), such as an alphanumeric input device, including alphanumeric and other keys for communicating information and/or command selections to the processors 1102-1106. Another type of user input device includes cursor control, such as a mouse, a trackball, or cursor direction keys for communicating direction information and command selections to the processors 1102-1106 and for controlling cursor movement on the display device.

System 1100 may include a dynamic storage device, referred to as main memory 1116, or a random access memory (RAM) or other computer-readable devices coupled to the processor bus 1112 for storing information and instructions to be executed by the processors 1102-1106. Main memory 1116 also may be used for storing temporary variables or other intermediate information during execution of instructions by the processors 1102-1106. System 1100 may include a read only memory (ROM) and/or other static storage device coupled to the processor bus 1112 for storing static information and instructions for the processors 1102-1106. The system set forth in FIG. 11 is but one possible example of a computer system that may employ or be configured in accordance with aspects of the present disclosure.

According to one embodiment, the above techniques may be performed by computer system 1100 in response to processor 1104 executing one or more sequences of one or more instructions contained in main memory 1116. These instructions may be read into main memory 1116 from another machine-readable medium, such as a storage device. Execution of the sequences of instructions contained in main memory 1116 may cause processors 1102-1106 to perform the process steps described herein. In alternative embodiments, circuitry may be used in place of or in combination with the software instructions. Thus, embodiments of the present disclosure may include both hardware and software components.

A machine readable medium includes any mechanism for storing or transmitting information in a form (e.g., software, processing application) readable by a machine (e.g., a computer). Such media may take the form of, but is not limited to, non-volatile media and volatile media. Non-volatile media includes optical or magnetic disks. Volatile media includes dynamic memory, such as main memory 816. Common forms of machine-readable medium may include, but is not limited to, magnetic storage medium (e.g., floppy diskette); optical storage medium (e.g., CD-ROM); magneto-optical storage medium; read only memory (ROM); random access memory (RAM); erasable programmable memory (e.g., EPROM and EEPROM); flash memory; or other types of medium suitable for storing electronic instructions.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only, and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims, or can be learned by the practice of the principles set forth herein.

What is claimed:

1. A method for monitoring an electrochemical device comprising:
obtaining, via a processing device, a measurement of a first characteristic of an electrochemical device during a first period of a waveform at the electrochemical device;
obtaining, via the processing device, a measurement of a second characteristic of the electrochemical device during a second period of a waveform at the electrochemical device, the second period occurring after the first period; and
calculating an operational characteristic for the electrochemical device based on the measurement of the first characteristic and the measurement of the second characteristic.

2. The method of claim 1 wherein the first characteristic is a charge current flowing to the electrochemical device and the second characteristic is a voltage across the electrochemical device.

3. The method of claim 2 wherein the operational characteristic is an impedance parameter of the electrochemical device, the impedance parameter used to harmonically tune a charge waveform providing the charge current flowing to the electrochemical device.

4. The method of claim 1, further comprising:
storing, in a first storage device, the measurement of the first characteristic and, in a second storage device, the measurement of the second characteristic.

5. The method of claim 4, further comprising:
retrieving, from the first storage device, the measurement of the first characteristic and, from the second storage device, the measurement of the second characteristic after the second period of the charge waveform.

6. The method of claim 1, further comprising:
controlling a charging circuit to shape the charge waveform to comprise a repeating charge signal, wherein each charge signal occurs within a period of the charge waveform.

7. The method of claim 1, further comprising:
obtaining a second measurement of the first characteristic of the electrochemical device during a third period of the charge waveform applied to the electrochemical device; and
averaging the measurement of the first characteristic and the second measurement of the first characteristic.

8. The method of claim 1, further comprising:
altering an attribute of the charge waveform based on the calculated operational characteristic for the electrochemical device.

9. The method of claim 8 wherein the charge waveform defines a body portion, the operational characteristic associated with the body portion, and altering the attribute of the charge waveform comprises altering a period of the body portion based on the operational characteristic.

10. The method of claim 9 wherein the altered period of the body portion is based on maintaining an impedance of the body portion within a threshold.

11. The method of claim 8 wherein the charge waveform defines a body portion, the operational characteristic associated with the body portion, and altering the attribute of the charge waveform comprises altering a frequency of a leading edge harmonic to modulate an impedance associated with the body portion.

12. The method of claim 3 wherein the impedance parameter comprises at least one of a real impedance value, an imaginary impedance value, a magnitude impedance value, a phase shift impedance value, or an admittance value.

13. The method of claim 8 wherein the charge waveform defines a leading edge, the operational characteristic associated with the leading edge, and altering the attribute of the charge waveform comprises altering a frequency of a leading edge harmonic to modulate an impedance associated with the leading edge.

14. A system for an electrochemical device comprising:
a processing unit operably coupled with a first memory and a second memory, the first memory including a first measurement of an electrochemical device and the second memory including a second measurement of the electrochemical device, the processing unit configured to compute an operational characteristic of the electrochemical device from the first measurement and the second measurement.

15. The system of claim 14 further comprising a first multiplexor operably coupled with the first memory and the second memory, the multiplexor controlled to sequence storage of the first measurement in the first memory and the second measurement in the second memory.

16. The system of claim 15 wherein the first measurement is stored in a first memory location of the first memory and the second measurement is stored in a second memory location of the second memory, wherein the first memory location is aligned with the second memory location.

17. The system of claim 16 further comprising a second multiplexor operably coupled with an analog to digital converter, the analog to digital converter operably coupled with the first multiplexor, the second multiplexor controlled to alternately access a first measurement circuit to obtain the first measurement and a second measurement circuit to obtain the second measurement, the analog to digital converter alternatively digitizing the first measurement and the second measurement and providing the digitized measurements to the first multiplexor to sequence storage of the first measurement in the first memory and the second measurement in the second memory.

18. The system of claim 14 wherein the operational characteristic is impedance.

19. The system of claim 18 wherein the first measurement is a current measurement responsive to a charge signal applied to the electrochemical device and the second measurement is a voltage measurement responsive to a charge signal applied to the electrochemical device, the controller calculating an impedance ratio from the current amplitude measurement and the corresponding voltage amplitude measurement and obtaining based on the impedance ratio, the impedance of the electrochemical device.

20. The system of claim 19, wherein the impedance comprises at least one of a real impedance value, an imaginary impedance value, a magnitude impedance value, or a phase shift impedance value.

21. The system of claim 19, wherein charge signal comprises a discrete charge period comprising a harmonically tuned leading edge portion and a body portion, different than the leading edge portion, following the leading edge portion.

22. The system of claim 21 wherein the harmonically tuned leading edge is a sinusoidal shape at a frequency based on impedance.

23. The system of claim 14 wherein the first measurement is a current measurement responsive to a charge signal applied to the electrochemical device and the second measurement is a voltage measurement responsive to a charge signal applied to the electrochemical device, the system further measuring a plurality of additional current measurements interleaved with a plurality of additional voltage measurements in a time window.

24. The system of claim 23 wherein the processing unit obtains an average of the current measurements and an average of the voltage measurements in the time window, and computes the operational characteristic of the electrochemical device related to impedance from the average of the current measurements and the average of the voltage measurements.

25. The system of claim 23 wherein the processing unit obtains a maximum current measurement and a maximum voltage measurement from the current measurements and voltage measurements, respectively, in the time window, and computes the operational characteristic of the electrochemical device related to impedance from the maximum current measurement and the maximum voltage measurement.

26. A system for an electrochemical device comprising:
a processing arrangement obtaining a first measurement of a first current from a first memory, the first measurement of an electrochemical device during a first period of a charge or discharge waveform at the electrochemical device;
the processing unit further obtaining a second measurement of a second voltage from a second memory, the second measurement of the electrochemical device during a second period of a charge or discharge waveform at the electrochemical device, the second period occurring after the first period; and
the processing unit further calculating an impedance characteristic for the electrochemical device based on the first measurement of the first current and the second measurement of the second voltage.

27. The system of claim 26 wherein the first measurement is a current amplitude responsive to a charge or discharge signal applied to the electrochemical device and the second measurement is a voltage amplitude responsive to a charge or discharge signal applied to the electrochemical device, the controller calculating an impedance ratio from the current amplitude measurement and the corresponding voltage amplitude measurement and obtaining based on the impedance ratio, the impedance characteristic of the electrochemical device.
